(19) United States
(12) Patent Application Publication
(10) Pub. No.: US 2015/0116016 A1
(43) Pub. Date: Apr. 30, 2015

(54) Dead-Zone Free Charge Pump Phase-Frequency Detector

(71) Applicant: Keysight Technologies, Inc., Minneapolis, MN (US)

(72) Inventor: Akmarul Ariffin Salleh, Penang (MY)

(21) Appl. No.: 14/068,073

(22) Filed: Oct. 31, 2013

(51) Int. Cl. H03L 7/089

(52) U.S. Cl. CPC H03L 7/0891
USPC 327/157

(57) ABSTRACT

A charge-pump phase-frequency detector includes first and second flip-flops first and second delay circuits, a charge pump circuit and a reset gate. The flip-flops each have a respective data input connected to a fixed logic level, a reset input, a data output, and a clock input. The clock inputs of the first and second flip-flops are connected to receive a frequency reference signal and a feedback signal derived from the VCO, respectively. The reset gate includes a respective input connected to the data output of each of the flip-flops, and an output connected to the reset inputs of the flip-flops via the first delay circuit. The charge pump circuit includes an up input connected to the data output of the first flip-flop via the second delay circuit, a down input connected to the data output of the second flip-flop, and a control current output.

### BACKGROUND

Phase-lock loop circuits are used in many applications for such purposes as generating clock signals having a defined frequency relationship to a frequency reference signal, such as a signal generated by a crystal-controlled oscillator, or for measuring changes in the frequency of an input signal. A phase-lock loop typically includes a charge pump phase-frequency detector, a loop filter, a voltage-controlled oscillator (VCO), and a frequency divider. The charge pump phase-frequency detector includes a phase-frequency detector, and a charge pump controlled by the phase-frequency detector. The VCO generates an AC signal that in most applications provides the output signal of the phase-lock loop. The frequency of the output signal depends on a control signal input to the VCO. The phase-frequency detector receives a frequency reference signal and a feedback signal generated by the frequency divider dividing the frequency of the output signal generated by the VCO. Depending on a phase and/or frequency difference between the feedback signal and the frequency reference signal, the phase-frequency detector controls the charge pump to deliver charge to, or to extract charge from, the loop filter to change the output of the loop filter. The changes in the output of the loop filter change the frequency of the output signal generated by the VCO in a way that reduces the phase and/or frequency difference between the feedback signal and the frequency reference signal. The phase-lock loop circuit achieves a lock state when the phase difference is reduced to zero.

In phase-lock loop circuits having a conventional integer frequency divider, the frequency of the output signal generated by the VCO is an integer multiple of the frequency of the frequency reference signal. In many applications, especially ones in which the frequency of the output signal is varied by changing the divisor of the frequency divider from one integer devisor to the next integer devisor, the frequency difference between adjacent integer multiples of the frequency of the frequency reference signal is greater than specified increments in the frequency of the output signal. Smaller increments in the frequency of the output signal that can be obtained using an integer frequency divider are obtained by employing a fractional-N frequency divider that divides the frequency of the output signal by a non-integer divisor. The fractional-N frequency divider divides by a non-integer divisor by dividing the frequency of the output signal by a number (e.g., 8) of different integer divisors that bracket the specified non-integer divisor. The integer divisors have respective duty cycles that together define the non-integer divisor.

In phase-lock loop circuits employing a fractional-N frequency divider and a conventional charge pump phase-frequency detector, the charge pump phase-frequency detector can behave non linearly when the phase difference between the feedback signal and the frequency reference signal is small. A charge pump phase-frequency detector that behaves non-linearly when the phase difference between the feedback signal and the frequency reference signal is small is said to exhibit a dead zone in which it is unable to accurately match the phase of the feedback signal to the frequency reference signal.

Accordingly, what is needed is a charge pump phase-frequency detector able to maintain linear control when the phase difference between the feedback signal and the frequency reference signal is small.

### BRIEF DESCRIPTION OF THE DRAWINGS

FIG. 1 is a block diagram showing an example of a phase-lock loop (PLL) circuit that includes a charge pump phase-frequency detector.

FIG. 2 is an example of a conventional charge pump phase-frequency detector.

FIG. 3 is a timing diagram showing the operation of the conventional charge pump phase-frequency detector shown in FIG. 2 with a large phase difference between the feedback signal and the frequency reference signal.

FIG. 4 is a timing diagram showing the operation of the conventional charge pump phase-frequency detector shown in FIG. 2 with a small phase difference between the feedback signal and the frequency reference signal.

FIG. 5 is a block diagram showing another example of a conventional charge pump phase-frequency detector incorporating a delay circuit.

FIG. 6 is a timing diagram showing examples of the source current sourced by and the sink current sunk by the conventional charge pump phase-frequency detector shown in FIG. 5.

FIG. 7 is a timing diagram showing how the current waveforms shown in FIG. 6 form a runt control current pulse.

FIG. 8 is a block diagram showing an example of a charge pump phase-frequency detector as disclosed herein.

FIG. 9 is a timing diagram showing an example of the largest phase difference between the source current and the sink current in the phase-lock loop circuit shown in FIG. 1.

FIG. 10 is a timing diagram showing the effect of delaying the up control signal in the charge pump phase-frequency detector shown in FIG. 8.

FIG. 11 is a timing diagram showing the control current output by an example of the charge pump phase-frequency detector shown in FIG. 8.

FIG. 12 is a timing diagram showing an example of the largest phase difference between the source current and the sink current in the phase-lock loop circuit shown in FIG. 1.

FIG. 13 is a timing diagram showing waveforms in an example of the charge pump phase-frequency detector shown in FIG. 8 in which the source current and sink current have long rise and fall times.

FIG. 14 is a block diagram showing another example of a charge pump phase-frequency detector as disclosed herein.

FIGS. 15A-15D are block diagrams each showing an example of the control signal delay circuit of the charge pump phase-frequency detector shown in FIG. 14.

FIG. 16 is a flowchart showing an example of a phase-frequency detection method as disclosed herein.

FIG. 17 is a flowchart showing an example of a method of generating an output signal having a frequency defined by a frequency reference signal based on the phase-frequency detection method shown in FIG. 16.

### DETAILED DESCRIPTION

Disclosed herein is a charge-pump phase-frequency detector (CPPFD) that detects differences in phase and/or frequency between two signals. In a typical application, a CPPFD is used to control the VCO of a phase-lock loop circuit. The CPPFD includes a first flip-flop, a second flip-flop, a first delay circuit, a second delay circuit, a charge pump circuit and a reset gate. The first flip-flop has a data input connected to a fixed logic level, a reset input, a data output, and a clock input connected to receive a frequency reference signal. The second flip-flop has a data input connected to fixed logic level, a reset input, a data output, and a clock input connected to receive a feedback signal derived from the VCO. The reset gate includes a first input connected to the data output of the first flip-flop, a second input connected to the data output of the second flip-flop and an output connected to the reset inputs of the flip-flops via the first delay circuit. The charge pump circuit includes an up input connected to the data output of the first flip-flop via the second delay circuit, a down input connected to the data output of the second flip-flop, and a control current output.

Also disclosed herein is a phase-lock loop circuit that includes a voltage-controlled oscillator (VCO), a frequency divider circuit, a sigma-delta modulator and the above-described CPPFD. The VCO is to generate an output signal, and has a control input coupled to the output of the charge pump circuit. The frequency divider circuit operates in response to instantaneous integer divisors generated by the sigma-delta modulator to divide the frequency of the output signal by a fractional-N divisor to generate the feedback signal received at the clock input of the second flip-flop of the CPPFD.

Also disclosed herein is a charge-pump phase-frequency detector (CPPFD) that includes a first flip-flop, a second flip-flop, a first delay circuit, a second delay circuit, a charge pump circuit and a reset gate. The first flip-flop has a data input connected to a fixed logic level, a reset input, a data output, and a clock input connected to receive a frequency reference signal. The second flip-flop has a data input connected to fixed logic level, a reset input, a data output, and a clock input connected to receive a feedback signal. The reset gate has a first input connected to the data output of the first flip-flop, a second input connected to the data output of the second flip-flop, and an output connected to the reset inputs of the flip-flops via the first delay circuit. The charge pump circuit has comprising an up input connected via the second delay circuit to receive an up control signal from the data output of the first flip-flop, a down input connected via the second delay circuit to receive a down control signal from the data output of the second flip-flop, and a control current output. The second delay circuit is to delay one of the up control signal and the down control signal relative to the other of the up control signal and the down control signal.

Also described disclosed herein is a phase-frequency detection method. In the method, a frequency reference signal and a feedback signal are received. A current source is provided to output a source current, and a current sink is provided to sink a sink current. The source current and the sink current are differenced to generate an output current representing a phase and/or frequency difference between the feedback signal and the frequency reference signal. An up control signal is set in response to an edge of the frequency reference signal, and a down control signal is set in response to an edge of the feedback signal. The up control signal and the down control signal are reset a defined first delay time after the lagging one of the up control signal and the down control signal has been set. One of the source current and the sink current is turned on and off in response to the setting and the resetting, respectively, of the up control signal, and the other of the source current and the sink current is turned on and off in response to the setting and the resetting, respectively, of the down control signal. One of the up control signal and the down control signal is delayed relative to the other of the up control signal and the down control signal.

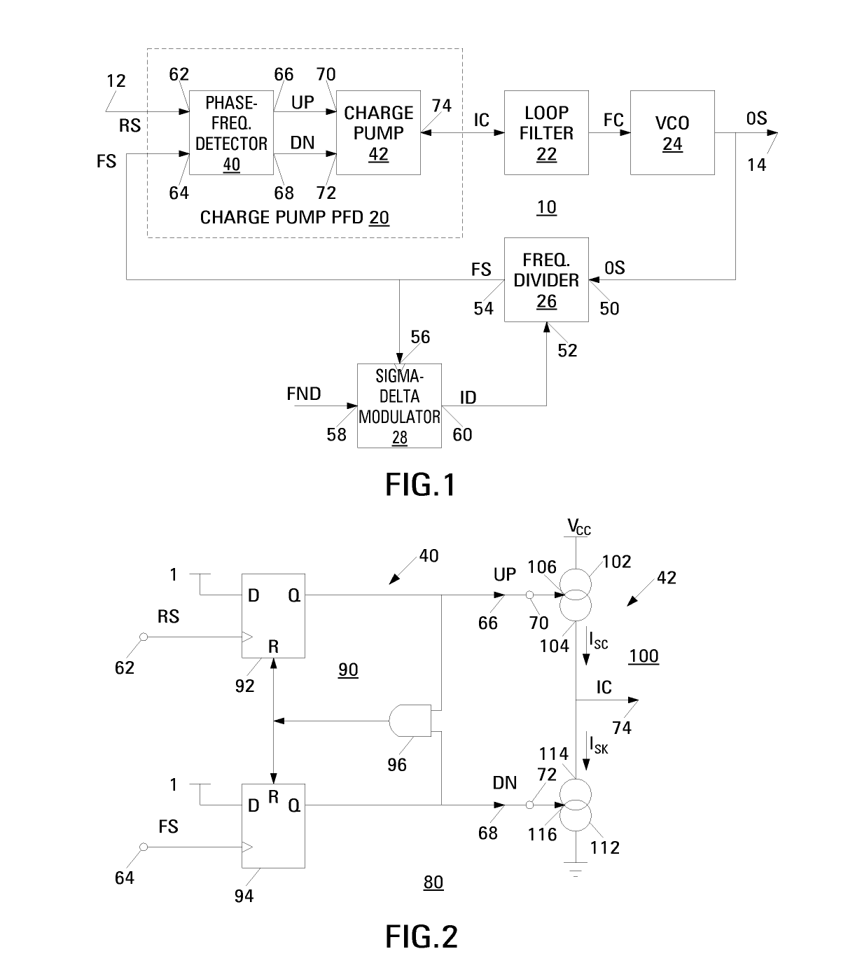

FIG. 1 is a block diagram showing an example 10 of a phase-lock loop (PLL) circuit that includes a charge pump phase-frequency detector 20. Phase-lock loop circuit 10 includes a frequency reference input 12 and an output 14. Phase-lock loop circuit 10 additionally includes a loop filter 22, a voltage-controlled oscillator (VCO) 24, a frequency divider 26 and a sigma-delta modulator 28. Charge pump phase-frequency detector 20 includes a phase-frequency detector 40 and a charge pump 42.

VCO 24 has a control input, and a signal output connected to output an output signal OS to the output 14 of PLL circuit 10. Frequency divider 26 has a signal input 50 connected to receive output signal OS from the output of VCO 24, an instantaneous integer divisor input 52, and a feedback output 54. Sigma-delta modulator 28 has a clock signal input 56 connected to receive feedback signal FS from the feedback output 54 of frequency divider 26, a fractional-N divisor input 58, and an instantaneous integer divisor output 60 connected to output an instantaneous integer divisor ID to the instantaneous integer divisor input 52 of frequency divider 26.

Within charge pump phase-frequency detector 20, phase-frequency detector 40 has a reference input 62 connected to receive a frequency reference signal RS from frequency reference input 12, a feedback input 64 connected to receive feedback signal FS from the feedback output 54 of frequency divider 26. Phase-frequency detector 40 additionally has an up output 66, and a down output 68. Charge pump 42 has an up input 70 connected to receive an up control signal UP from the up output 66 of phase-frequency detector 40, a down input 72 connected to receive a down control signal DN from the down output 68 of phase-frequency detector 40, and a control current output 74 coupled to the control input of VCO 24. In the example shown, the control current output 74 of charge pump 42 is coupled to the control output of VCO 24 by loop filter 22. Loop filter 22 has an input connected to receive a control current IC from the control current output 74 of charge pump 42, and a control output connected to output a frequency control signal FC to the control input of VCO 24.

In operation, VCO 24 generates output signal OS at a frequency that, after division by a fractional-N divisor N.F is equal to that of the frequency reference signal received by PLL circuit 10, where N and F the integer and fractional portions of the fractional-N divisor. The frequency at which VCO 24 generates output signal OS is controlled by frequency control signal FC received from charge pump phase-frequency detector 20 via loop filter 22. Frequency divider 26 generates feedback signal FS by dividing the frequency of output signal OS by the instantaneous integer divisor ID received from sigma-delta modulator 28. Instantaneous integer divisor ID is one of a set of integer divisors, sigma-delta modulator 28 receives feedback signal FS at its clock input and, for each period of the feedback signal, generates a respective instantaneous integer divisor ID such that the average of the instantaneous integer divisors is equal to the fractional-N divisor N.F specified by a fractional-N divisor signal FND received at fractional-N divisor input 58. Consequently, the frequency of feedback signal FS is 1/N.F of the frequency of output signal OS.

In charge pump phase-frequency detector 20, phase-frequency detector 40 receives frequency reference signal RS at reference input 62 and feedback signal FS at feedback input 64. In response to frequency reference signal RS and feedback signal FS, phase-frequency detector 40 outputs up control signal UP at up output 66 and down control signal DN at down output 68 with a temporal offset between them corresponding to the phase difference between frequency reference signal RS and feedback signal FS. Up control signal UP and down control signal DN control charge pump 42 to deliver control current IC to, or extract control current IC from, loop filter 22 to change frequency control signal FC output by the loop filter. The changes in frequency control signal FC output by loop filter 22 change the frequency at which VCO 24 generates output signal OS in a way that reduces the phase difference between feedback signal FS derived from output signal OS and frequency reference signal RS. PLL circuit 10 eventually reaches a lock state in which feedback signal FS is equal in frequency to, and is in phase with, reference signal RS, and in which the frequency of output signal OS is N.F times the frequency of reference signal RS, as defined by the fractional-N divisor N.F specified by fractional-N divisor signal FND.

FIG. 2 is a block diagram showing an example 80 of a conventional charge pump phase-frequency detector that can be used to implement charge pump phase-frequency detector 20 in a non-optimal embodiment of phase-lock loop circuit 10 described above with reference to FIG. 1. Conventional charge pump phase-frequency detector 80 includes an example 90 of a conventional phase-frequency detector that can be used to implement phase-frequency detector 40, and an example 100 of a charge pump that can be used to implement charge pump 42. Due to the ability of conventional phase-frequency detector 90 to generate what are known as runt pulses, an embodiment of PLL circuit 10 in which phase-frequency detector 40 is implemented using conventional phase-frequency detector 90 would have a dead zone in which conventional phase-frequency detector 90 would not linearly control the PLL circuit.

Conventional phase-frequency detector 90 includes a first flip-flop 92, a second flip-flop 94, and a reset gate 96. In the example shown, each of the flip-flops 92, 94 is a D-type flip-flop and includes a data input D, a clock input, a reset input R, and a non-inverting data output Q. A preset input or a clear input of the flip-flops may be used as reset input R. The data inputs D of flip-flops 92, 94 are connected to a fixed voltage corresponding to a high logic state or a low logic state. In the example shown, the fixed voltage corresponds to a high logic state. The reset inputs of flip-flops 92, 94, are connected to the output of reset gate 96. The clock input of flip-flop 92 is connected to receive frequency reference signal RS from reference input 62. The clock input of flip-flop 94 is connected to receive feedback signal FS from feedback input 64. The data output Q of flip-flop 92 is connected to output up control signal UP to up output 66 and to one of the inputs of reset gate 96. The data output Q of flip-flop 94 is connected to output down control signal DN to down output 68 and to the other of the inputs of reset gate 96. In the example shown, reset gate 96 is an AND gate. In other examples, flip-flops other than D-type flip-flops may be used as flip-flops 92, 94, and a gate other than an AND gate may be used as reset gate 96, respectively. Minor logic changes and/or the addition of one or more inverters may be necessary to enable other types of flip-flops and gates to be used.

Charge pump 100 includes up input 70, down input 72, and control current output 74 as described above with reference to FIG. 1. Charge pump 100 additionally includes a current source 102, and a current sink 112. Current source 102 has a current output 104 connected to control current output 74, and a control input 106 connected to receive up control signal UP from up input 70 connected to the up output 66 of conventional phase-frequency detector 130. Current sink 112 has a current input 114 connected to control current output 74 and a control input 116 connected to receive down control signal DN from down input 72 connected to the down output 68 of conventional phase-frequency detector 90.

In its high logic state (set state), up control signal UP received at the control input 106 of current source 102 turns current source 102 ON, in which state, the current source outputs a source current I_{SC}. In its low logic state (reset state), up control signal UP turns current source 102 OFF, in which state, the current source outputs substantially no current. In its high logic state (set state), down control signal DN received at the control input 116 of current sink 112 turns current sink 112 ON, in which state, the current sink sinks a sink current I_{SK}. In its low logic state (reset state), down control signal DN turns current sink 112 OFF, in which state, the current sink sinks substantially no current.

Sink current I_{SK} sunk by current sink 112 is substantially equal to source current I_{SC} output by current source 102. When up control signal UP and down control signal DN are in the low logic state, current source 102 is OFF and current sink 112 is OFF, so that charge pump 100 neither delivers current to, nor extracts current from, control current output 74 as control current IC. When only up control signal UP is in the high logic state, current source 102 is ON, current sink 112 is OFF, and current source 102 delivers source current I_{SC} to control current output 74 as control current IC. When only down control signal DN is in the high logic state, current source 102 is OFF, current sink 112 is ON, and current sink 112 extracts sink current I_{SK} from control current output 74 as control current IC. When both up control signal UP and down control signal DN are in the high logic state, current source 102 is ON, current sink 112 is ON, and current sink 112 sinks source current I_{SC} output by current source 102 as sink current I_{SK}, so that charge pump 100 neither delivers current to, nor extracts current from, control current output 74 as control current IC.

In another example (not shown) of a conventional charge pump phase-frequency detector, the sense of control current IC is opposite that of conventional charge pump phase-frequency detector 80. In such an example, up control signal UP controls current sink 112, and down control signal DN controls current source 102.

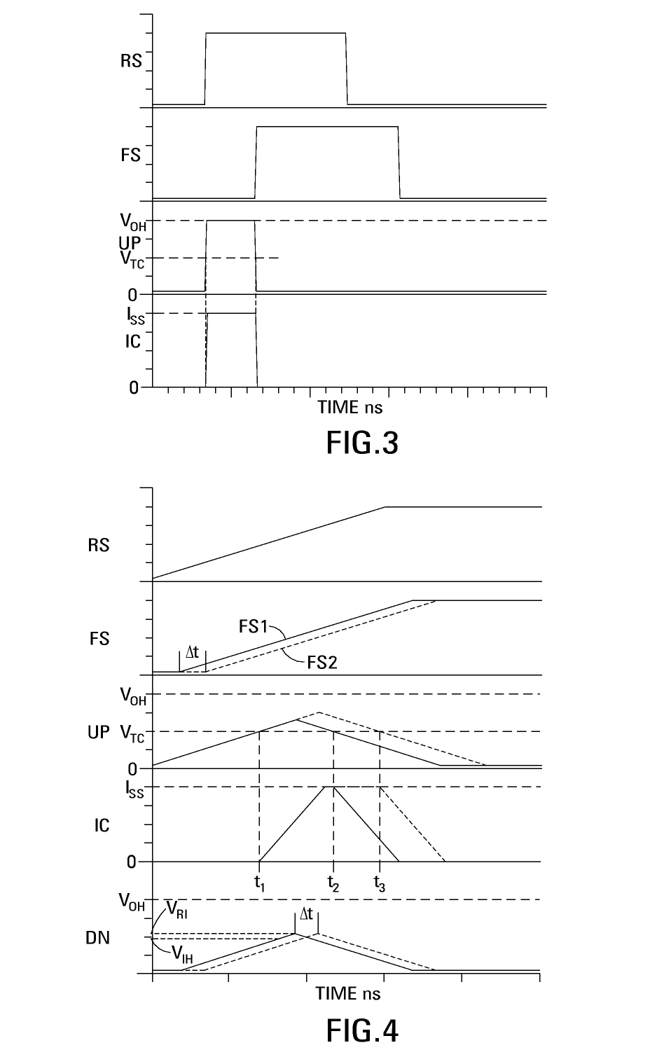

FIG. 3 is a timing diagram showing the operation of conventional charge pump phase-frequency detector 80. In the example shown, feedback signal FS lags frequency reference signal RS. Referring additionally to FIG. 2, initially, the data outputs Q of flip-flops 92, 94 are both in the low logic state. When frequency reference signal RS changes state, the rising edge of the frequency reference signal clocks the high logic state at the data input D of flip-flop 92 to the data output Q thereof, which causes up control signal UP to change from the low logic state to the high logic state. In the high logic state, up control signal UP is at a steady-state voltage V_{OH} corresponding to the high logic state. The low logic state at the data output Q of flip-flop 94 holds the output of reset gate 96 in the low logic state until feedback signal FS changes state. When feedback signal FS changes state, the rising edge of the feedback signal clocks the high logic state at the data input D of flip-flop 94 to the data output Q thereof, which causes down control signal DN to change towards the high logic state. The high logic states at both inputs of reset gate 96 cause the output of the reset gate to change to the high logic state. The high logic state at the reset inputs R of flip-flops 92, 94 resets the data outputs Q of flip-flops 92, 94 to the low logic state. This returns up control signal UP and down control signal DN to the low logic state,

Alternatively, when feedback signal FS leads frequency reference signal RS, the rising edge of feedback signal FS causes down control signal DN to change from the low logic state to the high logic state, but the low logic state at the data output Q of flip-flop 92 holds the output of reset gate in the low logic state. When frequency reference signal RS changes state, the data output Q of flip-flop 92 changes towards the high logic state, which causes reset gate 96 to reset the data outputs Q of flip-flops 92, 94 and, hence up control signal UP and down control signals DN to the low logic state.

In charge pump 100, the control inputs 106, 116 of current source 102 and current sink 112, respectively, have respective control thresholds. Current source 102 is ON or OFF depending on whether up control signal UP is greater than or less than, respectively, the control threshold of control input 106. Current sink 112 is ON or OFF depending on whether down control signal DN is greater than or less than, respectively, the control threshold of control input 116. To simplify the following description, control input 106 and control input 116 will be regarded as having the same control threshold V_{TC}, and control threshold V_{TC} will be regarded as being independent of whether the level of up control signal UP and down control signal DN, respectively, is increasing or decreasing.

When the data output Q of flip-flop 92 changes from the low logic state to the high logic state, and up control signal UP increases to a level at which it exceeds the control threshold V_{TC} of current source 102, current source 102 turns ON and outputs source current I_{SC} as control current IC. When the data outputs Q of flip-flops 92, 94 are reset from the high logic state to the low logic state, and up control signal UP falls to a level below the control threshold V_{TC} of current source 102, current source 102 turns OFF, and the level of control current IC returns to zero. When the data output Q of flip-flop 94 changes from the low logic state to the high logic state, and down control signal DN increases to a level at which it exceeds the control threshold V_{TC} of current sink 112, current sink 112 turns ON and sinks sink current I_{SK} as control current IC. When the data outputs of flip-flops 92, 94 are reset from the high logic state to the low logic state, and down control signal DN falls to a level below the control threshold V_{TC} of current sink 112, current sink 112 turns OFF, and the level of control current IC returns to zero.

Up control signal UP changing from the low logic state to the high logic state and later returning to the low logic state forms what will be referred to herein as an UP pulse. Down control signal DN changing from the low logic state to the high logic state and later returning to the low logic state forms what will be referred to herein in as a DN pulse. When feedback signal FS lags frequency reference signal RS, the pulse width of the UP pulse, and, hence, the pulse width of control current IC, depends on the phase difference between feedback signal FS and frequency reference signal RS. When feedback signal FS leads frequency reference signal RS, the pulse width of the DN pulse, and, hence, the pulse width of control current IC, depends on the phase difference between feedback signal FS and frequency reference signal RS.

Referring additionally to FIG. 1, in PLL circuit 10, frequency control signal FC, on which the frequency of output signal OS generated by VCO 24 depends, is linearly proportional to the average of control current IC output by charge pump 42 to loop filter 22 or received by charge pump 42 from loop filter 22. For relatively large phase differences, as exemplified in FIG. 3, the average of control current IC is linearly proportional to the pulse width of control current IC, and, hence, to the phase difference between feedback signal FS and frequency reference signal RS. While this linear relationship exists, charge pump phase-frequency detector 20 controls phase-lock loop circuit 10 substantially linearly.

Phase-lock loop circuit 10 operates differently, however, when the phase difference between feedback signal FS and frequency reference signal RS is comparable with the rise- and fall-times of the data outputs Q of flip-flops 92, 94. FIG. 4 is a timing diagram showing the operation of conventional charge pump phase-frequency detector 80 in an example in which the phase difference between feedback signal FS and frequency reference signal RS is small such that the temporal offset between feedback signal FS and frequency reference signal RS is less than the rise- and fall-times of the data outputs Q of flip-flops 92, 94. Note the expanded time scale in FIG. 4 compared with FIG. 3. The small time delay between frequency reference signal RS and feedback signal FS causes flip-flops 92, 94 to output the leading one of up control signal UP and down control signal DN as what will be referred to herein as a runt voltage pulse and is described further below.

The data outputs Q of flip-flops 92, 94 have a specified steady-state output voltage V_{OH} corresponding to the high logic state. The inputs of reset gate 96 have a specified minimum input voltage V_{IH} corresponding to the high logic state that is less than the specified steady-state voltage V_{OH} of the data outputs Q of flip-flops 92, 94. A runt pulse is a leading one of the UP pulse and the DN pulse whose peak level is less than the specified steady-state output voltage V_{OH} of the data outputs Q of flip-flops 92, 94.

In the example shown in FIG. 4, feedback signal FS lags frequency reference signal RS, so that down control signal DN lags up control signal UP. The one of up control signal UP and down control signal DN that lags the other control signal will sometimes be referred to herein as the lagging control signal. Similarly, the one of up control signal UP and down control signal DN that leads the other control signal will sometimes be referred to herein as the leading control signal. The rising edge of frequency reference signal RS causes the data output Q of flip-flop 92 (and up control signal UP) to change from the low logic state towards the high logic state. Then, before the voltage on the data output Q of flip-flop 92 (and up control signal UP) reaches steady-state output voltage V_{OH} corresponding to the high logic state, the rising edge of feedback signal FS causes the data output Q of flip-flop 94 (and down control signal DN) to change from the low logic state towards the high logic state. When the voltage at the data output Q of flip-flop 94 (and down control signal DN) reaches the minimum input voltage V_{IH} of reset gate 96 corresponding to the high logic state, the high logic states at both inputs of the reset gate cause the output of the reset gate to change to the high logic state. The high logic state at the reset inputs R of flip-flops 92, 94 resets the data outputs Q of flip-flops 92, 94 (and, hence, up control signal UP and down control signal DN), and the voltages at data outputs Q fall towards the low logic state.

However, the data outputs Q of flip-flops 92, 94 do not reset at the instant down control signal DN exceeds the specified minimum input voltage V_{IH} of reset gate 96 corresponding to the high logic state. Internal delays within reset gate 96 and second flip-flop 94 allow the voltages at the data output Q of flip-flop 94 and, hence, down control signal DN, to rise to a peak voltage level V_{RI} that is greater than the specified minimum input voltage V_{IH} of the reset gate before the voltage at the data output Q of flip-flop 94 starts to fall towards the low logic state as a result of the reset of flip-flop 94. Additionally, the internal delays within reset gate 96 and flip-flop 92 allow the voltage at the data output Q of flip-flop 92, and, hence, up control signal UP, to rise to a peak voltage level higher than the voltage attained by the up control signal at the instant down control signal DN reached minimum input voltage V_{IH} prior to the reset. However, the peak voltage level reached by up control signal UP is less than steady-state output voltage V_{OH}, so that the UP pulse is a runt pulse.

Alternatively, when feedback signal FS leads frequency reference signal RS, down control signal DN leads up control signal UP, and the up control signal is the lagging control signal that causes the output of reset gate 96 to change state when the up control signal exceeds minimum input voltage V_{IH}. The up control signal rises to peak voltage level V_{RI} that is greater than specified minimum input voltage V_{IH} before it starts to fall as a result of the reset of flip-flop 92. Peak voltage V_{RI} reached by the lagging control signal when the data outputs Q of flip-flops 92, 94 reset will be referred to herein as a reset input voltage. Additionally, the internal delays within reset gate 96 and flip-flop 94 allow the voltage at the data output Q of flip-flop 94, and, hence, down control signal DN, to rise to a peak voltage level higher than the voltage attained by the down control signal at the instant up control signal UP reached minimum input voltage V_{IH} prior to the reset. However, the peak voltage level reached by down control signal DN is less than steady-state output voltage V_{OH}, so that the DN pulse is a runt pulse in this case.

Referring additionally to FIG. 1, when the phase difference between feedback signal FS and frequency reference signal RS is so small that the leading control signal is a runt pulse, the average control current IC output by charge pump 42 controlled by phase-frequency detector 40 is no longer linearly proportional to the phase difference between feedback signal FS and reference signal RS, and charge pump phase-frequency detector 20 no longer linearly controls PLL circuit 10. FIG. 4 shows two examples of feedback signal FS: a feedback signal FS1 and a feedback signal FS2 delayed relative to feedback signal FS1 by a delay time ΔT. Feedback signal FS2 lags frequency reference signal RS by a greater lag than feedback signal FS1. Feedback signal FS1 and signals related to feedback signal FS1 are represented by solid lines. Feedback signal FS2 and signals related to feedback signal FS2 are represented by broken lines.

Frequency reference signal RS causes up control signal UP to change from the low logic state towards the high logic state. At a time t₁, the level of up control signal UP exceeds the control threshold V_{TC} of current source 102, and current source 102 outputs source current I_{SC} as control current IC. When up control signal UP is reset in response to feedback signal FS1, the up control signal resets shortly after the level of control current IC reaches its steady-state level I_{SS}, and before up control signal UP reaches steady-state output level V_{OH}. The reset causes the level of the up control signal to fall towards the low logic state. At a time t₂, the level of the up control signal falls below the control threshold V_{TC} of current source 102, and control current IC falls towards zero.

When up control signal UP is reset in response to feedback signal FS2, up control signal UP is reset later than when it was reset in response to feedback signal FS1 by a delay time equal to the delay time Δt between feedback signal FS2 and feedback signal FS1. When up control signal UP resets, the level of control current IC has again reached its steady-state level ISS, and, during delay time Δt, up control signal UP has reached a higher peak level. The reset causes the level of the up control signal to fall towards the low logic state but, because the up control signal reached a higher peak level before it was reset, the up control signal takes until time t₃ for its level to fall below the control threshold V_{TC} of current source 102, and for control current IC to begin to fall towards zero. Feedback signal FS2 is delayed relative to feedback signal FS1 by delay time Δt, but the additional width of the control current pulse IC resulting from the feedback signal FS2 (from time t₂ to time t₃) is substantially greater than delay time Δt. The non-linear relationship between the width of the control current pulse and the phase difference between feedback signal FS and frequency reference signal RS makes the relationship between the average of control current IC and the phase difference non-linear. Conventional charge pump phase-frequency detector 80 consequently exhibits a dead zone in a range of phase differences in which the relationship between the average control current IC output by charge pump 100 and the phase difference is non-linear.

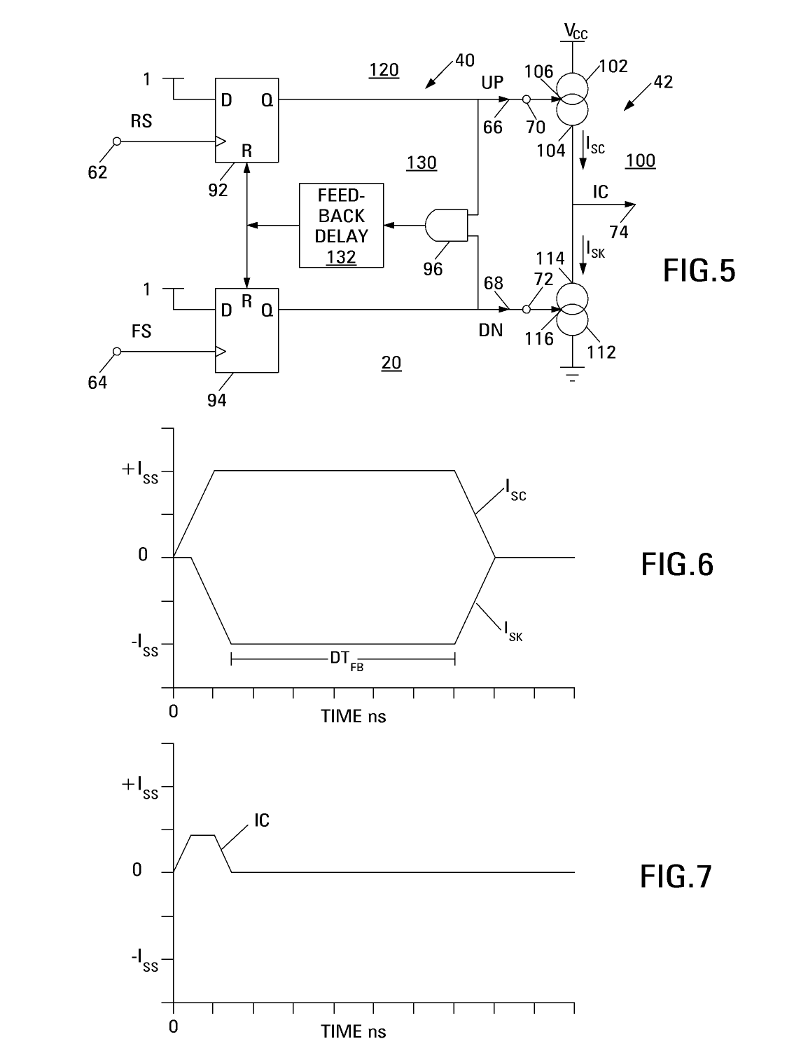

In conventional phase-frequency detectors similar to conventional phase-frequency detector 90, it is known to add a delay circuit between the output of the reset gate and the reset inputs of the flip-flops. However, the literature appears to be devoid of teaching on how to determine the minimum delay of the delay circuit. FIG. 5 is a block diagram showing another example 120 of a charge pump phase-frequency detector that could be used as charge pump phase-frequency detector 20 in another non-optimal embodiment of phase-lock loop circuit 10. Conventional charge pump phase-frequency detector 120 includes an example 130 of a conventional phase-frequency detector that includes a delay circuit between the output of reset gate 96 and the reset inputs of flip-flops 92, 94. Elements of conventional charge pump phase-frequency detector 120 that correspond to elements of conventional charge pump phase-frequency detector 80 described above with reference to FIG. 2 are indicated using the same reference numerals and will not be described again in detail.

In conventional charge pump phase-frequency detector 120, conventional phase-frequency detector 130 includes a feedback delay circuit 132 interposed between the output of reset gate 96 and the reset inputs of flip-flops 92, 94. Specifically, feedback delay circuit 132 has an input connected to the output of reset gate 96, and an output connected to the reset inputs R of flip-flops 92, 94. Feedback delay circuit 132 delays the reset of conventional phase-frequency detector 130 relative to the time at which the output of reset gate 96 changes state, i.e., the time at which the lagging input of the reset gate reaches minimum input voltage V_{IH} with the leading input already exceeding minimum input voltage V_{IH}. The delay time imposed by feedback delay circuit 132 allows both up control signal UP and down control signal DN to reach the steady-state output voltage V_{OH} corresponding to the high logic state before conventional phase-frequency detector 130 is reset and control signals UP and DN once more return to the low logic state.

To prevent conventional phase-frequency detector 130 from outputting up control signal UP and down control signal DN as runt pulses, feedback delay circuit 132 imposes a minimum delay time DT_{FB} sufficient to delay the reset of flip-flops 92, 94 until the voltage at the data outputs Q of flip-flops 92, 94 has had time to reach steady-state voltage V_{OH} corresponding to the high logic state. The delay time needed for the voltage at the data outputs Q of flip-flops 92, 94 to reach steady-state voltage V_{OH} corresponding to the high logic state is the time needed for the voltage at the data output Q of the lagging one of flip-flops 92, 94 to increase from reset input voltage V_{RI} to steady-state voltage V_{OH} corresponding to the high logic state. Delay time DT_{FB} can be calculated from the specified maximum rise time of data outputs Q from the low logic state to the high logic state as follows:

$${DT}_{FB} \geq \frac{{V}_{OH} - {V}_{RI}}{{V}_{OH} - {V}_{OL}} \cdot {TR}_{LH}$$

in which:

DT_{FB} is the delay time of feedback delay circuit 132;

V_{OH} is the steady-state voltage at the data outputs of flip-flops 92, 94 corresponding to the high logic state;

V_{RI} is the reset input voltage, as defined above;

V_{OL} is the steady-state voltage at the data outputs of flip-flops 92, 94 corresponding to the low logic state; and

TR_{LH} is the rise time of the outputs of flip-flops 92, 94 from the low logic state to the high logic state.

However, when conventional phase-frequency detector 130 is used to control a charge pump, such as charge pump 42 described above with reference to FIG. 1, feedback delay circuit 132, even with a minimum delay configured as described above, does not provide a complete solution to the problem of runt pulses because conventional phase-frequency detector 130 can generate runt current pulses.

FIG. 6 is a timing diagram showing the source current I_{SC} sourced by current source 102 and the sink current I_{SK} sunk by current sink 112 in conventional charge pump phase-frequency detector 120. Initially, up control signal UP and down control signal DN are both in the low logic state, and current source 102 and current sink 112 are both OFF. When the UP control signal changes to the high logic state, current source 102 turns ON, but current sink 112 remains OFF. When the DN control signal changes to the high logic state, current sink 112 turns ON, and current source 102 remains ON. Feedback delay circuit 132 between the output of reset gate 96 and the reset inputs R of flip-flops 92, 94 prevents current source 102 and current sink 112 from turning OFF until the end of the delay time of feedback delay circuit 132.

The delay time imposed by feedback delay circuit 132 provides sufficient time for up control signal UP and down control signal DN to reach steady-state output voltage V_{OH}, and for both source current I_{SC} and sink current I_{SK} to reach their respective steady-state values +I_{SS}, −I_{SS} before current source 102 and current sink 112 are turned off by the reset of up control signal UP and down control signal DN. At first sight, it would appear that conventional phase-frequency detector 130 would not be subject to a dead zone in that that the current pulses shown in FIG. 6 are wide enough to allow source current I_{SC} and sink current I_{SK} to reach their steady-state values, and thus avoid the runt pulse problem. However, the control current IC output at control current output 74 is actually the difference between source current I_{SC} sourced by current source 102 and sink current I_{SK} sunk by current sink 112:

IC=I_{SC}−I_{SK}.

FIG. 7 is a timing diagram showing an example of control current IC resulting from the exemplary waveforms of source current I_{SC} and sink current I_{SK} shown in FIG. 6. In the example shown in FIGS. 6 and 7, the time delay between source current I_{SC} output when current source 102 is turned ON by the up control signal and sink current I_{SK} sunk when current sink 112 is turned ON by the down control signal is comparable with the rise times of the source current and sink current. Consequently, when the up control signal UP turns current source 102 ON, source current I_{SC} starts to increase towards its steady-state level I_{SS}. Current sink 112 remains OFF, so source current I_{SC} is output as control current IC. Down control signal DN turns current sink 112 ON before source current I_{SC} reaches its steady-state level I_{SS}. When current sink 112 turns ON, sink current I_{SK} starts to increase towards its steady-state level −I_{SS}. The increasing level of sink current I_{SK} prevents control current IC from increasing, despite the increasing level of source current I_{SC}. Once source current I_{SC} reaches its steady-state level, the increasing level of sink current I_{SK} causes control current IC to decrease. Control current IC decreases to zero when both sink current I_{SK} reaches its steady-state level, and source current I_{SC} is at its steady-state level. The maximum level of control current IC in the example shown in FIG. 7 is less than one-half of the steady-state level I_{SS} of source current shown in FIG. 6. Accordingly, the control current pulse shown in FIG. 7 can be regarded as being another runt pulse

Additionally, FIG. 6 shows source current I_{SC} and sink current I_{SK} falling exactly at the same time and with the same fall time. In reality, source current I_{SC} and sink current I_{SK} fall at different times and with different fall times. This can lead to another runt control current pulse occurring at the falling edges of the current pulses.

Referring additionally to FIG. 1, as noted above, the frequency of output signal OS generated by VCO 24 depends on the average of control current IC output by charge pump phase-frequency detector 20. The average of control current IC is the control current integrated over time. When the phase difference between feedback signal FS and frequency reference signal RS is large, the pulse width of control current IC is linearly proportional to the phase difference, and the level of the control current is independent of the phase difference. However, when the phase difference is sufficiently small that the control current pulse is a runt pulse, the pulse width of the control current and the level of the control current both depend on the phase difference. As a result, the average of the control current is not linearly proportional to the phase difference, and linear control of PLL circuit 10 by charge pump phase-frequency detector 20 is lost.

In phase-lock loop circuit 10 having frequency divider 26 controlled by sigma-delta modulator 28 to divide the frequency of output signal OS by a fractional-N divisor, a charge pump phase-frequency detector subject to a dead zone is problematic when the frequency of output signal OS generated by VCO 24 is an integer multiple N of the frequency of frequency reference signal RS. Even though instantaneous integer divisor ID generated by sigma-delta modulator 28 varies from ID=N−3 to ID=N+4 in an example in which sigma-delta modulator 28 is a 3rd-order sigma-delta modulator and N is the integer portion of the fractional-N divisor, when instantaneous integer divisor ID=N, the rising edges of frequency reference signal RS align with the rising edges of feedback signal FS, and the phase difference between the feedback signal and the frequency reference signal is small. When the phase difference is small, runt pulses of control current IC cause a loss of linear control in phase-lock loop circuit 10.

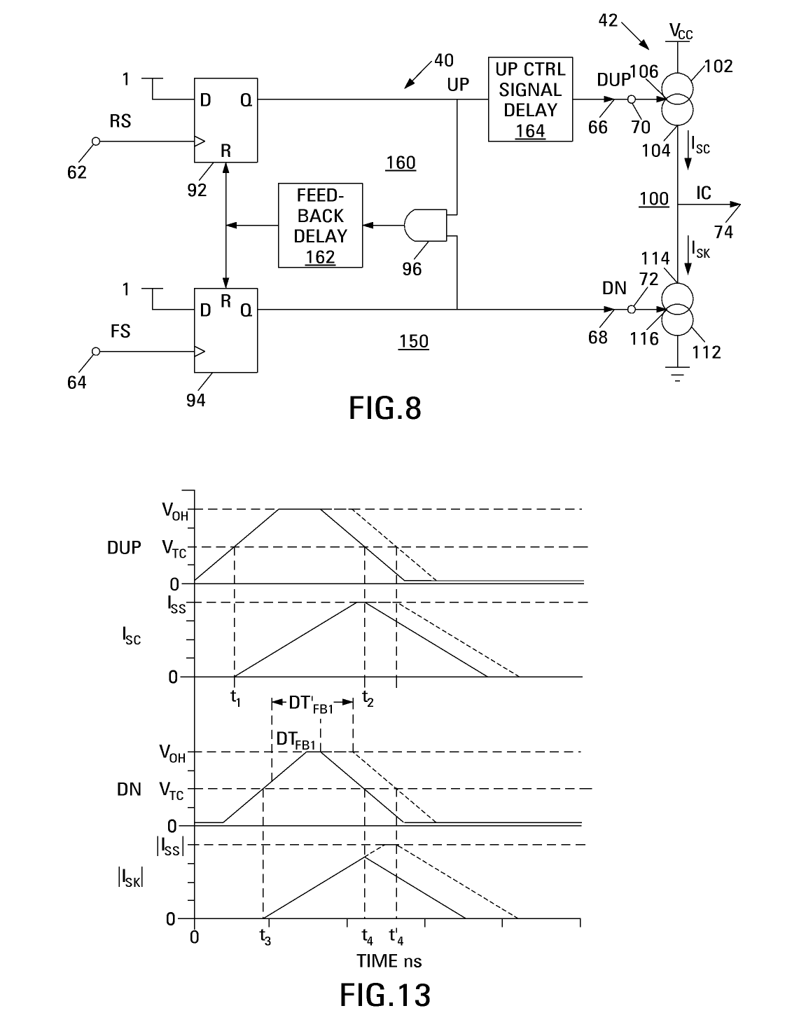

FIG. 8 is a block diagram showing an example 150 of a charge pump phase-frequency detector as disclosed herein. Charge pump phase-frequency detector 150 includes an example 160 of phase-frequency detector 40 and additionally includes charge pump 100, described above with reference to FIG. 5, controlled by phase-frequency detector 160. Elements of charge pump phase-frequency detector 150 that correspond to elements of conventional charge pump phase-frequency detector 120 described above with reference to FIG. 5 are indicated using the same reference numerals and will not be described again in detail. In charge pump phase-frequency detector 150, phase-frequency detector 160 includes a first delay circuit, namely, feedback delay circuit 162, interposed between the output of reset gate 96 and the reset inputs of flip-flops 92, 94. Specifically, feedback delay circuit 162 has an input connected to the output of reset gate 96, and an output connected to the reset inputs R of flip-flops 92, 94. Feedback delay circuit 162 delays the reset of phase-frequency detector 160 relative to the time at which the output of reset gate 96 changes state to ensure that up control signal UP and down control signal DN can rise to steady-state voltage V_{OH} corresponding to the high logic state before the control signals are reset. This prevents phase-frequency detector 160 from outputting the leading one of the up control signal UP and the down control signal DN as a runt voltage pulse.

Phase-frequency detector 160 additionally includes a second delay circuit, namely, up control signal delay circuit 164, interposed between the data output Q of flip-flop 92 and up output 66. Specifically, up control signal delay circuit 164 has an input connected to the data output Q of flip-flop 92, and an output connected to up output 66. It should be noted that the input of reset gate 96 is connected directly to the data output Q of flip-flop 92, and not via up control signal delay circuit 164. Up control signal delay circuit 164 delays up control signal UP to provide a delayed up control signal DUP that is output at up output 66.

In the example shown in FIG. 8, in which delayed up control signal DUP controls current source 102 and down control signal DN controls current sink 112, up control signal delay circuit 164 delays the operation of current source 102 relative to the changes in state of the data output Q of flip-flop 92 to ensure that sink current I_{SK} always leads source current I_{SC}, and that the rising edge of source current I_{SC} does not overlap the rising edge of sink current I_{SK}. A rising edge is an edge on which the magnitude of the current is increasing.

In the example (not shown) described above in which the sense of the control current is opposite that of control current IC in charge pump phase-frequency detector 150, delayed up control signal DUP controls current sink 112 and down control signal DN controls current source 102. In this example, up control signal delay circuit 164 delays the operation of current sink 112 relative to the changes in state of the data output Q of flip-flop 92 to ensure that the magnitude of control current IC can increase to the steady-state level −I_{SS} of sink current I_{SK} before delayed up control signal DUP resets and turns current sink 112 OFF. Specifically, the delay imposed by up control signal delay circuit 164 is sufficient to ensure that source current I_{SC} always leads sink current I_{SK}, and that the rising edge of sink current I_{SK} does not overlap the rising edge of source current I_{SC}. By substituting current sink for current source, current source for current sink, sink current for source current, and source current for sink current, the descriptions below of charge pump phase-frequency detector 150 can be applied to this example.

Charge pump 100 can be said to include current source 102 and current sink 112. Current source 102 is to output to control current output 74 a source current I_{SC} in response to one of (a) up control signal UP delayed by up control signal delay circuit 164 (which provides a second delay), and (b) down control signal DN. Current sink 112 is to receive from control current output 74 a sink current I_{SK} in response to the other of (a) up control signal UP delayed by the up control signal delay circuit 164, and (b) down control signal DN. The difference between source current I_{SC} and sink current I_{SK} constitutes control current IC.

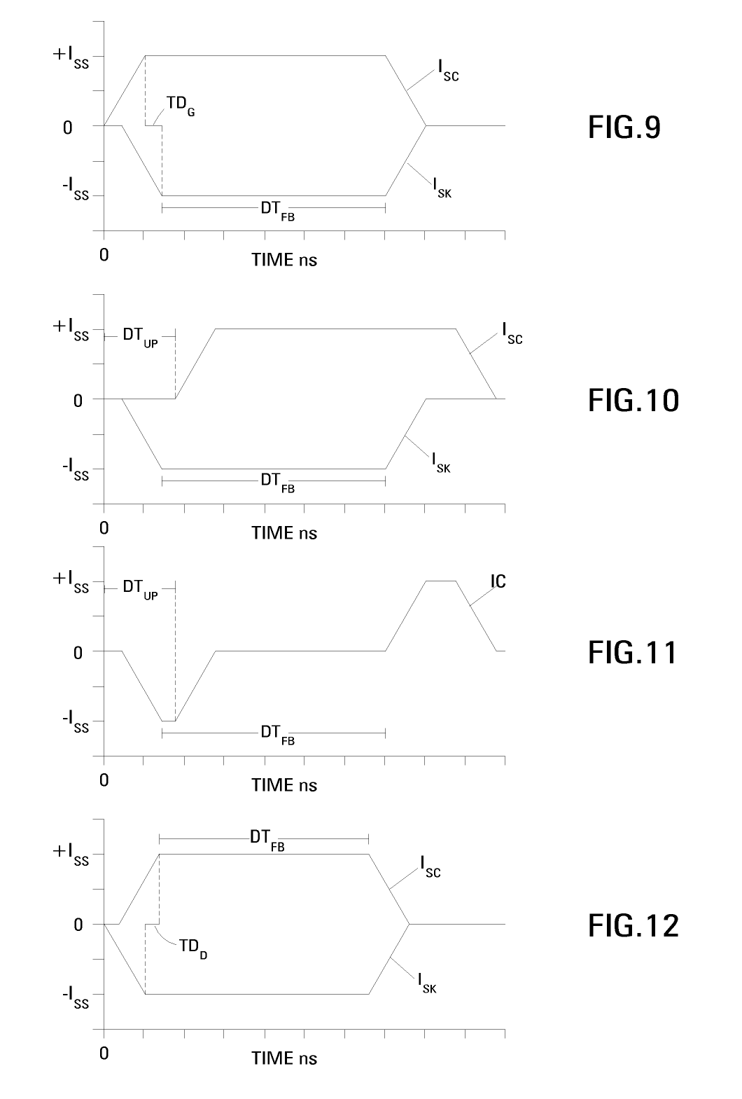

FIG. 9 is a timing diagram showing the largest time delay between the source current I_{SC} sourced by current source 102 and the sink current I_{SK} sunk by current sink 112 in an example of conventional charge pump phase-frequency detector 120 described above with reference to FIG. 5 when feedback signal FS lags frequency reference signal RS so that sink current I_{SK} lags source current I_{SC}. When feedback signal FS lags frequency reference signal RS, the time delay between feedback signal FS and reference signal RS is largest when the instantaneous integer divisor ID generated by sigma-delta modulator 28 is a maximum. A 3rd-order sigma-delta modulator generates a maximum instantaneous integer divisor ID of N+4. A 4th order sigma-delta modulator generates a maximum instantaneous integer divisor ID of N+8. In FIG. 9, TD_{G} indicates the largest time delay between feedback signal FS and frequency reference signal RS and, hence, between sink current I_{SK} and source current I_{SC}, when the feedback signal lags the frequency reference signal. In an example, largest time delay TD_{G} occurs when the instantaneous integer divisor ID generated by a 3rd-order sigma-delta modulator is N+4, or when the instantaneous integer divisor ID generated by a 4th-order sigma-delta modulator is N+8. Other orders of sigma-delta modulator have corresponding maximum instantaneous integer divisors when the feedback signal lags the frequency reference signal.

Up control signal delay circuit 164 prevents charge pump phase-frequency detector 150 from generating control current IC as a runt pulse by delaying the changes of state of the data output Q of flip-flop 92 output at up output 66 as delayed up control signal DUP such that source current I_{SC} is turned on and off delayed relative to sink current I_{SK} by a delay time sufficient to ensure that sink current I_{SK} always leads source current I_{SC}, and that the rising edge of source current I_{SC} does not overlap the rising edge of sink current I_{SK}. To achieve this condition, up control signal delay circuit 164 is configured to impose a delay time DT_{UP} on the changes of state of up control signal UP greater than the sum of the largest time delay between feedback signal FS and frequency reference signal RS, and the larger of the rise time of the source current of the sink current, i.e.:

DT_{UP}≧TD_{G}+max(TR_{SC},TR_{SK})

where:

DT_{UP} is the delay time imposed by up control signal delay circuit 164;

TD_{G} is the largest time delay between feedback signal FS and frequency reference signal RS when the feedback signal lags the frequency reference signal;

TR_{SC} is the rise time of source current I_{SC}; and

TR_{SK} is the rise time of sink current I_{SK}.

The rise times of the source current and the sink current are from zero to steady-state current I_{SS}.

FIG. 10 is a timing diagram showing the effect of up control signal delay circuit 164 delaying up control signal UP and, hence, source current I_{SC}, by a delay time equal to minimum delay time DT_{UP} in charge pump phase-frequency detector 150. FIG. 10 also shows sink current I_{SK}, and delay time DT_{FB} imposed by feedback delay circuit 162. In FIG. 10, the waveform of sink current I_{SK} is the same that described above with reference to FIG. 9. The data output Q of flip-flop 92 and, hence up control signal UP, neither of which is shown in FIG. 10, start to change from the low logic state state to the high logic state at a time corresponding to time 0 in FIG. 10. Up control signal delay circuit 164 delays the up control signal by delay time DT_{UP}, so that delayed up control signal DUP does not turn source current I_{SC} ON until after the magnitude of sink current I_{SK} has increased to its steady-state value −I_{SS}. Consequently, up control signal delay circuit 164 prevents the rising edge of the source current I_{SC} controlled by delayed up control signal DUP from overlapping the rising edge of the sink current I_{SK} controlled by down control signal DN, and ensures that sink current I_{SK} always leads source current I_{SC}. This ensures that the magnitude of control current IC reaches a level corresponding to the steady-state level of sink current I_{SK}, and prevents control current IC from being output as a runt pulse. The data outputs Q of flip-flops 92, 94 are reset delayed relative to the time that down control signal DN changes state by the delay time DT_{FB} imposed by feedback delay circuit 162. The reset of the data output Q of flip-flop 94 turns sink current I_{SK} OFF substantially immediately, but up control signal delay circuit 164 subjects the reset of the data output Q of flip-flop 92 to a delay time so that source current I_{SC} turns off after sink current I_{SK}. This ensures that the magnitude of control current IC reaches levels corresponding to the steady-state levels of sink current I_{SK} and source current I_{SC}, respectively, and prevents control current IC from being output as runt pulses.

FIG. 11 is a timing diagram showing the waveform of the control current IC resulting from differencing the waveforms of source current I_{SC} and sink current I_{SK} shown in FIG. 10. In the example shown, control current IC exhibits a negative pulse at the rising edges of the current pulses shown in FIG. 10, and a positive pulse at the falling edges of the current pulses. The negative pulse results from delaying source current I_{SC} such that the rising edges of source current I_{SC} and sink current I_{SK} do not overlap. The negative pulse has a peak magnitude equal to steady-state value −I_{SS} and a pulse width linearly proportional to the phase difference between feedback signal FS and frequency reference signal RS. The positive pulse results from delaying source current I_{SC} such that the falling edges of source current I_{SC} and sink current I_{SK} do not overlap. The positive pulse has a peak magnitude equal to steady-state value −I_{SS} and a constant pulse width. Consequently, the average value of control current IC is proportional to the phase difference

As noted above, to prevent phase-frequency detector 160 from generating the leading one of up control signal UP and down control signal DN as a runt pulse, feedback delay circuit 162 imposes a delay time greater than the product of:

the quotient of:
the difference between the voltage of the control signals corresponding the set state, and the maximum voltage attained by the lagging one of the control signals when control signals are reset, and
the difference between the voltage of the control signals corresponding to the set state, and the voltage of the control signals corresponding to the reset state, and

the rise time of the control signals from the reset state to the set state, i.e.,:

$${DT}_{FB 1} \geq \frac{{V}_{OH} - {V}_{RI}}{{V}_{OH} - {V}_{OL}} \cdot {TR}_{LH}$$

where:

DT_{FB1} is the delay time of feedback delay circuit 162 that prevents the leading one of the up control signal and the down control signal from being generated as a runt pulse; and

V_{OH}, V_{RI}, V_{OL}, and TR_{LH} are as defined above.

However, in phase-frequency detector 160 incorporating up control signal delay circuit 164, feedback delay circuit 162 is subject to additional constraints that prevent the delayed rising edge of source current c from overlapping the falling edge of sink current I_{SK}. When feedback signal FS lags frequency reference signal RS, to prevent the delayed rising edge of source current I_{SC} from overlapping the falling edge of sink current I_{SK}, feedback delay circuit 162 imposes a delay time DT_{FB2G} greater than the greater of the rise time of the source current and the rise time of the sink current, i.e.:

DT_{FB2G}≧max(TR_{SC},TR_{SK})

FIG. 12 is a timing diagram showing the largest time delay between the source current I_{SC} sourced by current source 102 and the sink current I_{SK} sunk by current sink 112 in an example of conventional charge pump phase-frequency detector 120 described above with reference to FIG. 5 when feedback signal FS leads frequency reference signal RS so that sink current I_{SK} leads source current I_{SC}. When feedback signal FS leads frequency reference signal RS, the magnitude of the time delay between frequency reference signal RS and feedback signal FS is largest when the instantaneous integer divisor ID generated by sigma-delta modulator 28 is a minimum. A 3rd-order sigma-delta modulator generates a minimum instantaneous integer divisor ID of N−3. A 4th-order sigma-delta modulator generates a minimum instantaneous integer divisor ID of N−7. In FIG. 12, TD_{D} represents the largest time delay between frequency reference signal RS and feedback signal FS when the feedback signal FS leads the frequency reference signal RS. In an example, largest time delay TD_{D} occurs when a 3rd-order sigma-delta modulator generates an instantaneous integer divisor ID of N−3, or when a 4th-order sigma-delta modulator generates and instantaneous divisor ID of N−7. Other orders of sigma-delta modulator have corresponding minimum instantaneous integer divisors when the feedback signal leads the frequency reference signal.

When feedback signal FS leads frequency reference signal RS, so that sink current I_{SK} leads source current I_{SC}, to prevent the delayed rising edge of source current I_{SC} from overlapping the falling edge of sink current I_{SK}, feedback delay circuit 162 imposes a delay time DT_{FB2D} given by:

DT_{FB2D}≧TD_{G}+max(TR_{SC},TR_{SK}).

To prevent the delayed rising edge of source current I_{SC} from overlapping the falling edge of sink current I_{SK} regardless of whether feedback signal FS leads frequency reference signal RS, or vice versa, feedback delay circuit 162 imposes a delay time DT_{FB2} given by:

DT_{FB2}≧max{DT_{FB2G},DT_{FB2D}}.

Since TD_{G}>TD_{D},

DT_{FR2G}≧DT_{FR2D}, and

DT_{FB2}≧TD_{G}+max(TR_{SC},TR_{SK}).

Thus, to prevent phase-frequency detector 160 from generating the leading one of the up control signal UP and the down control signal DN as a runt pulse, and to prevent the delayed rising edge of source current I_{SC} from overlapping the falling edge of sink current I_{SK} regardless of whether feedback signal FS leads frequency reference signal RS, or vice versa, feedback delay circuit 162 imposes a delay time DT_{FB} given by:

$${DT}_{FB} \geq max \{ {DT}_{FB 1} , {DT}_{FB 2} \} , \\ i . e . \\ {DT}_{FB} \geq max \{ \frac{{V}_{OH} - {V}_{RI}}{{V}_{OH} - {V}_{OL}} \cdot {TR}_{LH} , {TD}_{G} + max ( {TR}_{SC} , {TR}_{SK} ) \} .$$

Thus, expressed in words, feedback delay circuit 162 imposes a delay time DT_{FB} greater than the greater of:
a product of:
   a quotient of:
      a difference between the voltage at the data outputs of the flip-flops corresponding a high logic state and the reset input voltage of the reset gate; and
      a difference between the voltage at the data outputs of the flip-flops corresponding to the high logic state, and the voltage at the data outputs of the flip-flops corresponding to the low logic state, and
   the rise time of the data outputs of the flip-flops from the low logic state to the high logic state; and
a sum of:
   the largest time delay between the feedback signal and frequency reference signal when the feedback signal lags frequency reference signal, and
   the greater of the rise time of the sink current and the rise time of the source current.

In the following description, the term lagging control signal refers to the one of delayed up control signal DUP and down control signal DN that lags the other of the control signals, the term lagging current generator refers to the one of current source 102 and current sink 112 controlled by the lagging control signal, and the term lagging control current refers to the current I_{SC} or I_{SK} output or sunk by the lagging current generator. In the examples of source current I_{SC} and sink current I_{SK} shown in FIG. 10, delay time DT_{FB} is long enough to enable both source current I_{SC} and sink current I_{SK} to increase to their respective steady-state values I_{SS}. In some embodiments of charge pump phase-frequency detector 150, source current I_{SC} and/or sink current I_{SK} have a relatively long rise such that the elapsed time between the rising and falling edges of the lagging control signal crossing the control threshold of the lagging current generator is less than the rise time of the lagging control current. In such embodiments, delay time DT_{FB1} in the inequality stated immediately above may be insufficient to prevent control current IC being output as a runt current pulse. Specifically, when the peak current output by the lagging current generator is less than steady-state value I_{SS}, the positive control current pulse or the negative control current pulse is output as a runt pulse, and charge pump phase-frequency detector 150 no longer linearly controls phase lock loop circuit 10.

FIG. 13 is a timing diagram showing delayed up control signal DUP, source current I_{SC}, down control signal DN, and the magnitude of sink current I_{SK} in an example of charge pump phase-frequency detector 150 described above with reference to FIG. 8 in which source current I_{SC} and sink current I_{SK} have long rise times. In the example shown in FIG. 13, delayed up control signal DUP has a delay time of 0 relative to up control signal UP only to simplify the drawing and the following description. Also in the example shown in FIG. 13, feedback delay circuit 162 imposes a delay time equal to delay time DT_{FB1}, described above. At time 0, delayed up control signal DUP changes state and the level of delayed up control signal DUP increases from the low logic state towards the high logic state. When the level of the delayed up control signal exceeds the control threshold V_{TC} of current source 102 at time t₁, the level of source current I_{SC} output by current source 102 starts to increase towards its steady-state level I_{SS}. Delay time DT_{FB1} imposed by feedback delay circuit 162 is sufficient to enable delayed up control signal DUP to reach the steady-state voltage V_{OH} corresponding to the high logic state. When flip-flops 92, 94 are reset, the level of delayed up control signal DUP decreases from the high logic state towards the low logic state. When the level of the delayed up control signal falls below the control threshold V_{TC} of current source 102 at time t₂, the level of source current I_{SC} output by current source 102 starts to decrease towards zero. However, delay time DT_{FB1} is sufficient to enable source current I_{SC} to reach its steady-state level I_{SS} before the delayed up control signal falls below the control threshold V_{TC}, notwithstanding the slow rise time of source current I_{SC}. Consequently, the source current is not output as a runt pulse.

At a time after time 0 corresponding to the phase delay between feedback signal FS and frequency reference signal RS (FIG. 1), down control signal DN (the lagging control signal in this example) changes state and the level of down control signal DN increases from the low logic state towards the high logic state. When the level of the down control signal exceeds the control threshold V_{TC} of current sink 112 (the lagging current generator in this example) at time t₃, the magnitude of sink current I_{SK} sunk by current sink 112 starts to increase towards its steady-state level I_{SS}. Again, delay time DT_{FB1} imposed by feedback delay circuit 162 is sufficient to enable down control signal DN to reach the steady-state voltage V_{OH} corresponding to the high logic state. When flip-flops 92, 94 are reset, the level of down control signal DN decreases from the high logic state towards the low logic state. When the level of the down control signal falls below the control threshold V_{TC} of current sink 112 at time t₄, the magnitude of sink current I_{SK} sunk by current sink 112 starts to decrease towards zero. However, the slow rise time of sink current I_{SK} means that delay time DT_{FB1} is insufficient to enable the magnitude of sink current I_{SC} to reach steady-state level I_{SS} before the down control signal falls below the control threshold V_{TC}, and the magnitude of sink current I_{SK} starts to fall. Consequently, the sink current is output as a runt pulse.

To prevent source current I_{SC} and sink current I_{SK} from being output as a respective runt pulse, delay time DT_{FB1} is increased by a time sufficient to enable both source current I_{SC} and sink current I_{SK} to reach their respective steady-state levels before the lagging control signal (down control signal DN in this example) falls below the control threshold V_{TC} of the lagging current generator. Delay time DT_{FB1} as defined above is increased to delay the reset of flip-flops 92, 94 to make the elapsed time between time t₃ and t₄ at which the rising and falling edges, respectively, cross the control threshold of the lagging control signal greater than the rise time of the lagging control current.

FIG. 13 additionally shows the waveforms generated by an example of charge pump phase-frequency detector 150 in which feedback delay circuit 162 imposes an increased delay time DT′_{FB1} that is increased relative to delay time DT_{FB1} such that down control signal DN crosses the control threshold V_{TC} of current sink 112 at a time t′₄ such that the time that elapses between time t₃ and t′₄ is greater than the rise time of the current output by the lagging current generator, i.e., sink current I_{SK} in the example shown. The waveforms resulting from increased delay time DT′_{FB1} are shown in FIG. 13 by broken lines. Increased delay time DT′_{FB1} enables the level of sink current I_{SK} to reach its steady-state level before down control signal DN turns current sink 112 off. Increased delay time DT′_{FB1} is given by:

$${DT}_{FB 1} = {DT}_{FB 1} + max ( 0 , \{ max ( {TR}_{SC} , {TR}_{SK} ) - [ \{ \frac{{V}_{OH} - {V}_{TC}}{{V}_{OH} - {V}_{OL}} \cdot {TR}_{LH} \} - \{ \frac{{V}_{OH} - {V}_{TC}}{{V}_{OH} - {V}_{OL}} \cdot {TF}_{HL} \} ] \} ) = \{ \frac{{V}_{OH} - {V}_{RI}}{{V}_{OH} - {V}_{OL}} \cdot {TR}_{LH} \} + max ( 0 , \{ max ( {TR}_{SC} , {TR}_{SK} ) - [ \{ \frac{{V}_{OH} - {V}_{TC}}{{V}_{OH} - {V}_{OL}} \cdot {TR}_{LH} \} - \{ \frac{{V}_{OH} - {V}_{TC}}{{V}_{OH} - {V}_{OL}} \cdot {TF}_{HL} \} ] \} ) ,$$

where:

DT′_{FB1} is the increased delay time,

V_{TC} is the control threshold of the lagging current generator,

TR_{LH} is the rise time of the lagging control signal from the low logic state to the high logic state,

TF_{HL} is the fall time of the lagging control signal from the high logic state to the low logic state, and

DT_{FB1}, TR_{SC}, TR_{SK}, V_{OH}, V_{OL} are as defined above.

Consequently, the delay time DT′_{FB} imposed by feedback delay circuit 162 is greater than the greater of:

$$\{ \frac{{V}_{OH} - {V}_{RI}}{{V}_{OH} - {V}_{OL}} \cdot {TR}_{LH} \} + max ( 0 , \{ max ( {TR}_{SC} , {TR}_{SK} ) - [ \{ \frac{{V}_{OH} - {V}_{TC}}{{V}_{OH} - {V}_{OL}} \cdot {TR}_{LH} \} - \{ \frac{{V}_{OH} - {V}_{TC}}{{V}_{OH} - {V}_{OL}} \cdot {TF}_{HL} \} ] \} ) , \\ and$$

$${TD}_{G} + max ( {TR}_{SC} , {TR}_{SK} ) .$$

Thus, in embodiments of charge pump phase-frequency detector 150 in which the elapsed time between the rising and falling edges of the lagging control signal crossing the control threshold of the lagging current generator is less than the greater of the rise times of the source current and the sink current, feedback delay circuit 162 imposing delay time DT′_{FB} prevents phase-frequency detector 160 from generating the leading one of up control signal UP and down control signal DN as a runt voltage pulse, prevents the delayed rising edge of source current I_{SC} from overlapping the falling edge of sink current I_{SK} regardless of whether feedback signal FS leads frequency reference signal RS, or vice versa, and prevents control current IC from being output as a runt current pulse.

Referring again to FIG. 1, an embodiment of phase-lock loop circuit 10 using charge pump phase-frequency detector 150 as charge pump phase-frequency detector 20, and in which feedback delay circuit 162 and up control signal delay circuit 164 are configured to provide minimum delay times DT_{UP} and DT_{FB} as defined above, will operate linearly over the entire range of the instantaneous divisors ID input to frequency divider 26 by sigma-delta modulator 28.

In the example of charge pump phase-frequency detector 150 described above with reference to FIG. 8, up control signal delay circuit 164 delays up control signal UP to ensure that one of source current I_{SC} and sink current I_{SK} always leads the other of source current I_{SC} and sink current I_{SK}, and to prevent the rising edges of source current I_{SC} and sink current I_{SK} from overlapping. Additionally or alternatively, down control signal DN may be delayed to ensure that one of source current I_{SC} and sink current I_{SK} always leads the other of source current I_{SC} and sink current I_{SK}, and to prevent the rising edges of source current I_{SC} and sink current I_{SK} from overlapping.

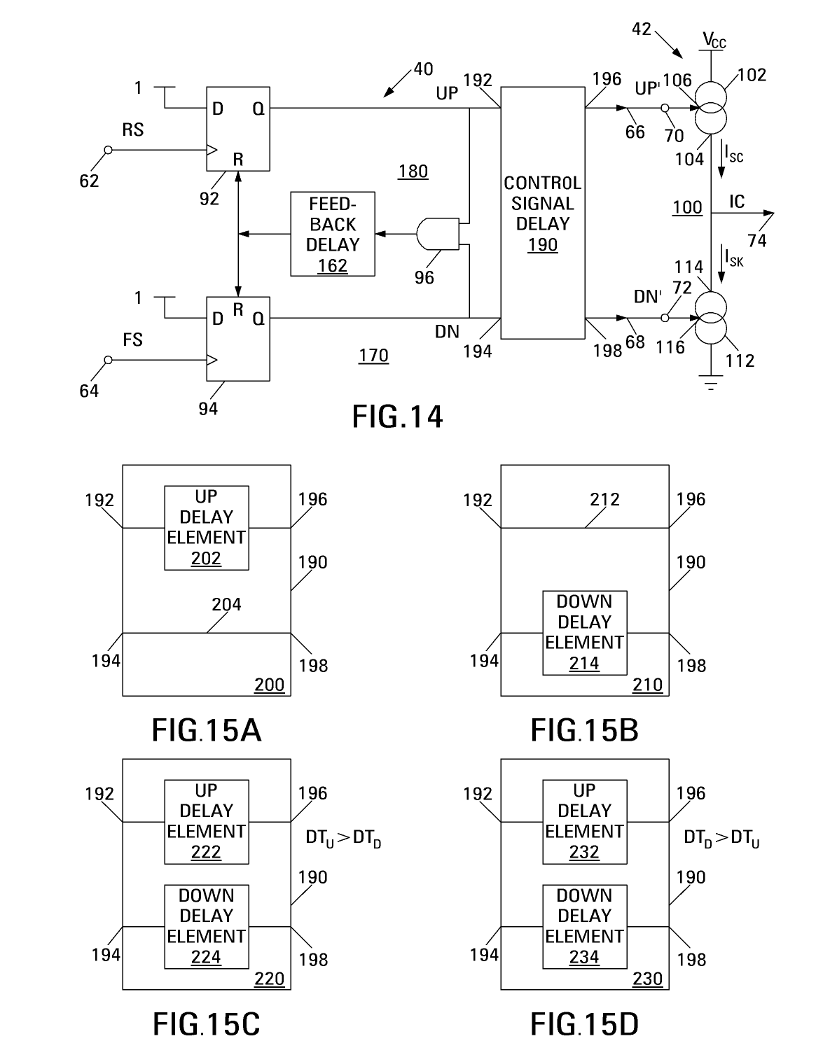

FIG. 14 is a block diagram showing another example 170 of a charge pump phase-frequency detector as disclosed herein. Charge pump phase-frequency detector 170 includes another example 180 of phase-frequency detector 40 and additionally includes charge pump 100, described above with reference to FIG. 5, controlled by phase-frequency detector 180. Elements of charge pump phase-frequency detector 170 that correspond to elements of conventional charge pump phase-frequency detector 120 described above with reference to FIG. 5 and to charge pump phase-frequency detector 150 described above with reference to FIG. 8 are indicated using the same reference numerals and will not be described again in detail.

In charge pump phase-frequency detector 170, phase-frequency detector 180 includes a first delay circuit, namely, feedback delay circuit 162, interposed between the output of reset gate 96 and the reset inputs of flip-flops 92, 94. Specifically, feedback delay circuit 162 has an input connected to the output of reset gate 96, and an output connected to the reset inputs R of flip-flops 92, 94. Feedback delay circuit 162 delays the reset of phase-frequency detector 160 relative to the time at which the output of reset gate 96 changes state. As described above with reference to FIG. 8. feedback delay circuit 162 has a delay time that ensures that up control signal UP and down control signal DN can rise to steady-state voltage V_{OH} corresponding to the high logic state before the control signals are reset. This prevents phase-frequency detector 180 from outputting the leading one of the up control signal UP and the down control signal DN as a runt voltage pulse.

Phase-frequency detector 180 additionally includes a second delay circuit, namely, control signal delay circuit 190, interposed between the data output Q of flip-flop 92 and the up output 66 of phase-frequency detector 180 and between the data output Q of flip-flop 94 and the down output 68 of phase-frequency detector 180. Specifically, control signal delay circuit 190 has an up input 192 connected to the data output Q of flip-flop 92, a down input 194 connected to the data output Q of flip-flop 94, and up output 196 connected to the up output 66 of phase-frequency detector 180 and a down output 198 connected to the down output 68 of phase-frequency detector 180. It should be noted that the inputs of reset gate 96 are connected directly to the data outputs Q of flip-flops 92, 94 and not via control signal delay circuit 190. Control signal delay circuit 190 delays one of up control signal UP and down control signal DN relative to the other of up control signal UP and down control signal DN to provide an up control signal UP′ that is output at up output 66 and a down control signal DN′ that is output at down output 68.

In the example shown in FIG. 14, in which up control signal UP′ controls current source 102 and down control signal DN′ controls current sink 112, control signal delay circuit 190 delays the one of the up control signal and the down control signal relative to the other of the up control signal and the down control signal by a delay time sufficient to ensure that the current controlled by the other of the up control signal and the down control signal always leads the current controlled by the one of the up control signal and the down control signal, and to prevent the rising edges of source current I_{SC} and sink current I_{SK} from overlapping. A rising edge is an edge on which the magnitude of the current is increasing.

In the example (not shown) described above in which the sense of the control current is opposite that of control current IC generated by charge pump phase-frequency detector 170, up control signal UP′ controls current sink 112 and down control signal DN′ controls current source 102. Again, in this example, control signal delay circuit 190 delays the one of the up control signal and the down control signal relative to the other of the up control signal and the down control signal by a delay time sufficient to ensure to ensure that the current controlled by the other of the up control signal and the down control signal always leads the current controlled by the one of the up control signal and the down control signal, and to prevent the rising edges of source current I_{SC} and sink current I_{SK} from overlapping. By substituting current sink for current source, current source for current sink, sink current for source current, and source current for sink current, the descriptions below of charge pump phase-frequency detector 170 can be applied to this example.

FIG. 15A shows an example 200 of control signal delay circuit 190 that delays the up control signal relative to the down control signal. Control signal delay circuit 200 includes an up delay element 202 connected between up input 192 and up output 196, and a conductor 204 connected between down input 194 and down output 198. Conductor 204 negligibly delays down control signal DN so that down control signal DN′ is negligibly delayed relative to down control signal DN. Up delay element 202 delays up control signal UP so that up control signal UP′ is delayed relative to down control signal DN. Up delay element 202 has a delay time DT_{UP} that ensures that sink current I_{SK} (controlled by the non-delayed down control signal DN′) always leads source current I_{SC} (controlled by the delayed up control signal UP′), and that prevents the rising edges of source current I_{SC} and sink current I_{SK} from overlapping.

In control signal delay circuit 200, the delay time DT_{UP} of up delay element 202 is greater than the sum of the largest time delay between the feedback signal and the frequency reference signal when the feedback signal lags the frequency reference signal, and the greater of the rise time of the source current and the rise time of the sink current, i.e.,

DT_{UP}≧TD_{G}+max(TR_{SC},TR_{SK}),

where TD_{G}, TR_{SC}, and TR_{SK} are as defined above.

FIG. 15B shows an example 210 of control signal delay circuit 190 that delays the down control signal relative to the up control signal. Control signal delay circuit 210 includes a conductor 212 connected between up input 192 and up output 196, and a down delay element 214 connected between down input 194 and down output 198. Conductor 212 negligibly delays up control signal UP so that up control signal UP′ is negligibly delayed relative to up control signal UP. Down delay element 214 delays down control signal DN so that down control signal DN′ is delayed relative to up control signal UP′. Down delay element 214 has a delay time DT_{DN} that ensures that source current I_{SC} (controlled by the non-delayed up control signal UP′) always leads sink current I_{SK} (controlled by the delayed down control signal DN′), and that prevents the rising edges of sink current I_{SK} and source current I_{SC} from overlapping.

In control signal delay circuit 210, the delay time DT_{DN} of down delay element 214 is greater than the sum of the largest time delay between the feedback signal and the frequency reference signal when the feedback signal leads the frequency reference signal, and the greater of the rise time of the source current and the rise time of the sink current, i.e.,

DT_{DN}≧TD_{D}+max(TR_{SC},TR_{SK}),

where TD_{D}, TR_{SC}, and TR_{SK} are as defined above.

FIG. 15C shows another example 220 of control signal delay circuit 190 that delays the up control signal relative to the down control signal. Control signal delay circuit 220 includes an up delay element 222 connected between up input 192 and up output 196, and a down delay element 224 connected between down input 194 and down output 198. Down delay element 224 delays down control signal DN by a non-zero delay time DT_{D} so that down control signal DN′ is delayed relative to down control signal DN. Up delay element 222 delays up control signal UP by a non-zero delay time DT_{U} so that up control signal UP′ is delayed relative to up control signal UP. In this example, the delay time DT_{U} of up delay element 222 is greater than the delay time DT_{D} of down delay element 224 so that up control signal UP′ is delayed relative to down control signal DN′. The difference DT_{UP} between the delay time DT_{U} of up delay element 222 and the delay time DT_{D} of down delay element 224 ensures that sink current I_{SK} (controlled by the less-delayed down control signal DN′) always leads source current I_{SC} (controlled by the more-delayed up control signal UP′), and prevents the rising edges of source current I_{SC} and sink current I_{SK} from overlapping.

In control signal delay circuit 220, the difference DT_{UP} between the delay time DT_{U} of up delay element 222 and the delay time DT_{D} of down delay element 224 is greater than the sum of the largest time delay between the feedback signal and the frequency reference signal when the feedback signal lags the frequency reference signal, and the greater of the rise time of the source current and the rise time of the sink current, i.e.,

DT_{UP}≧TD_{G}+max(TR_{SC},TR_{SK}),

where TD_{G}, TR_{SC}, and TR_{SK} are as defined above.

FIG. 15D shows another example 230 of control signal delay circuit 190 that delays the down control signal relative to the up control signal. Control signal delay circuit 230 includes an up delay element 232 connected between up input 192 and up output 196, and a down delay element 234 connected between down input 194 and down output 198. Up delay element 232 delays up control signal UP by a non-zero delay time DT_{UP} so that up control signal UP′ is delayed relative to up control signal UP. Down delay element 234 delays down control signal DN by a non-zero delay time DT_{D} so that down control signal DN′ is delayed relative to up control signal UP′. In this example, the delay time DT_{D} of down delay element 234 is greater than the delay time DT_{U} of up delay element 232 so that down control signal DN′ is delayed relative to up control signal UP′. The difference DT_{DN} between the delay time DT_{D} of down delay element 234 and the delay time DT_{U} of up delay element 232 ensures that source current I_{SC} (controlled by less-delayed up control signal UP′) always leads sink current I_{SK} (controlled by more-delayed down control signal DN′), and prevents the rising edges of sink current I_{SK} and source current I_{SC} from overlapping.

In control signal delay circuit 230, the difference DT_{DN} between the delay time DT_{D} of down delay element 234 and the delay time DT_{U} of up delay element 232 is greater than the sum of the largest time delay between the feedback signal and the frequency reference signal when the feedback signal leads the frequency reference signal, and the greater of the rise time of the source current and the rise time of the sink current, i.e.,

DT_{DN}≧TD_{D}+max(TR_{SC},TR_{SK}),

where TD_{D}, TR_{SC}, and TR_{SK} are as defined above.

In charge pump phase-frequency detector 170, the delay time DT_{FB} imposed by feedback delay circuit 162 is given by:

$${DT}_{FB} \geq max \{ \frac{{V}_{OH} - {V}_{RI}}{{V}_{OH} - {V}_{OL}} \cdot {TR}_{LH} , {TD}_{L} + max ( {TR}_{SC} , {TR}_{SK} ) \}$$

where DT_{FB}, V_{OH}, V_{RI}, V_{OL}, TR_{LH}, TR_{SC} and TR_{SK} are as defined above, and time delay TD_{L} is defined as follows. In embodiments, such as in the examples described above with reference to FIGS. 15A and 15C, in which control signal delay circuit 190 delays the up control signal relative to the down control signal, TD_{L} is the largest time delay between the feedback signal and the frequency reference signal when the feedback signal lags frequency reference signal. In embodiments, such as in the examples described above with reference to FIGS. 15B and 15D, in which control signal delay circuit 190 delays the down control signal relative to the up control signal, TD_{L} is the largest time delay between the feedback signal and the frequency reference signal when the feedback signal leads the frequency reference signal.

Thus, expressed in words, feedback delay circuit 162 imposes a delay time DT_{FB} greater than the greater of:
a product of:
   a quotient of:
      a difference between the voltage at the data outputs of the flip-flops corresponding a high logic state and the reset input voltage of the reset gate; and
      a difference between the voltage at the data outputs of the flip-flops corresponding to the high logic state, and the voltage at the data outputs of the flip-flops corresponding to the low logic state, and
   the rise time of the data outputs of the flip-flops from the low logic state to the high logic state; and
a sum of:
   the largest time delay between the feedback signal and frequency reference signal when the feedback signal lags frequency reference signal, and
   the greater of the rise time of the sink current and the rise time of the source current.

In examples of charge pump phase-frequency detector 170 in which source current I_{SC} and sink current I_{SK} have long rise times, as described above, feedback delay circuit 162 imposes an increased delay time DT′_{FB} greater than the greater of:

$$\{ \frac{{V}_{OH} - {V}_{RI}}{{V}_{OH} - {V}_{OL}} \cdot {TR}_{LH} \} + max ( 0 , \{ max ( {TR}_{SC} , {TR}_{SK} ) - [ \{ \frac{{V}_{OH} - {V}_{TC}}{{V}_{OH} - {V}_{OL}} \cdot {TR}_{LH} \} - \{ \frac{{V}_{OH} - {V}_{TC}}{{V}_{OH} - {V}_{OL}} \cdot {TF}_{HL} \} ] \} ) , \\ and$$

$${TD}_{L} + max ( {TR}_{SC} , {TR}_{SK} ) .$$

where V_{OH}, V_{RI}, V_{OL}, V_{TC}, TR_{LH}, TR_{SC}, TR_{SK}, TF_{HL} and TD_{L}, are as defined above.

Referring again to FIG. 1, an embodiment of phase-lock loop circuit 10 using charge pump phase-frequency detector 170 as charge pump phase-frequency detector 20, and in which feedback delay circuit 162 is configured to provide a minimum delay time DT_{FB} (as defined above) and control signal delay circuit 190 is configured to provide a minimum delay time DT_{UP} or DT_{DN} (as defined above), as appropriate, will operate linearly over the entire range of the instantaneous divisors ID input to frequency divider 26 by sigma-delta modulator 28.

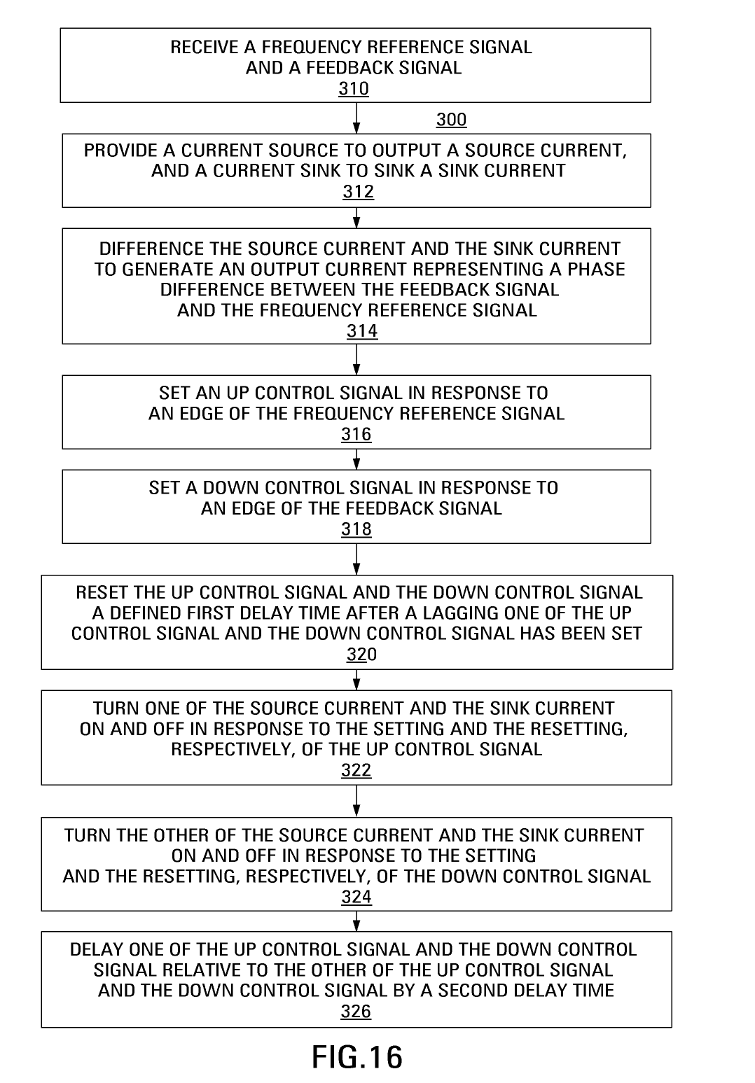

FIG. 16 is a flowchart showing an example 300 of a phase-frequency detection method as disclosed herein.

In block 310, a frequency reference signal and a feedback signal are received.

In block 312, a current source to output a source current, and a current sink to sink a sink current are provided.

In block 314, the source current and the sink current are differenced to generate an output current representing a phase difference between the feedback signal and the frequency reference signal;

In block 316, an up control signal is set in response to an edge of the frequency reference signal.

In block 318, a down control signal is set in response to an edge of the feedback signal.

In block 320, the up control signal and the down control signal are reset a defined first delay time after the lagging one of the up control signal and the down control signal has been set.

In block 322, one of the source current and the sink current is turned on and off in response to the setting and the resetting, respectively, of the up control signal.

In block 324, the other of the source current and the sink current is turned on and off in response to the setting and the resetting, respectively, of the down control signal.

In block 326, one of the up control signal and the down control signal is delayed relative to the other of the up control signal and the down control signal by a second delay time.

In an example, the charge pump phase-frequency detector 150 described above with reference to FIG. 8 performs an embodiment of method 300. In charge pump phase-frequency detector 150, the data output Q of flip-flop 92 provides the up control signal, and the data output Q of flip-flop 94 provides the down control signal, feedback delay circuit 162 defines the first delay time, and up control signal delay circuit 164 defines the second delay time. In another example, the charge pump phase-frequency detector 170 described above with reference to FIG. 14 performs an embodiment of method 300. In charge pump phase-frequency detector 170, the data output Q of flip-flop 92 provides the up control signal, and the data output Q of flip-flop 94 provides the down control signal, feedback delay circuit 162 defines the first delay time, and control signal delay circuit 190 defines the second delay time.

In an example, first delay time DT_{FB} is given by:

$${DT}_{FB} \geq max \{ \frac{{V}_{OH} - {V}_{RI}}{{V}_{OH} - {V}_{OL}} \cdot {TR}_{LH} , {TD}_{L} + max ( {TR}_{SC} , {TR}_{SK} ) \} ,$$

where DT_{FB}, V_{OH}, V_{RI}, V_{OL}, TR_{LH}, TD_{L}, TR_{SC} and TR_{SK} are as defined above.

In an example in which the up control signal is delayed relative to the down control signal, second delay time DT_{UP} is given by:

DT_{UP}≧TD_{G}+max(TR_{SC},TR_{SK}).

In an example in which the down control signal is delayed relative to the up control signal, second delay time DT_{DN} is given by:

DT_{DN}≧TD_{D}+max(TR_{SC},TR_{SK}).

where DT_{UP}, DT_{DN}, TD_{G}, TD_{D}, TR_{SC} and TR_{SK} are as defined above.

In an example in which the elapsed time between the rising and falling edges of the lagging control signal crossing the control threshold of the lagging current generator is less than the rise time of the lagging current, the increased first delay time DT′_{FB} is greater than the greater of:

$$\{ \frac{{V}_{OH} - {V}_{RI}}{{V}_{OH} - {V}_{OL}} \cdot {TR}_{LH} \} + max ( 0 , \{ max ( {TR}_{SC} , {TR}_{SK} ) - [ \{ \frac{{V}_{OH} - {V}_{TC}}{{V}_{OH} - {V}_{OL}} \cdot {TR}_{LH} \} - \{ \frac{{V}_{OH} - {V}_{TC}}{{V}_{OH} - {V}_{OL}} \cdot {TF}_{HL} \} ] \} ) , \\ and$$

$${TD}_{L} + max ( {TR}_{SC} , {TR}_{SK} ) ,$$

where V_{OH}, V_{RI}, V_{OL}, V_{TC}, TR_{LH}, TF_{HI}, TR_{SC}, TR_{SK}, and TD_{L} are as defined above.

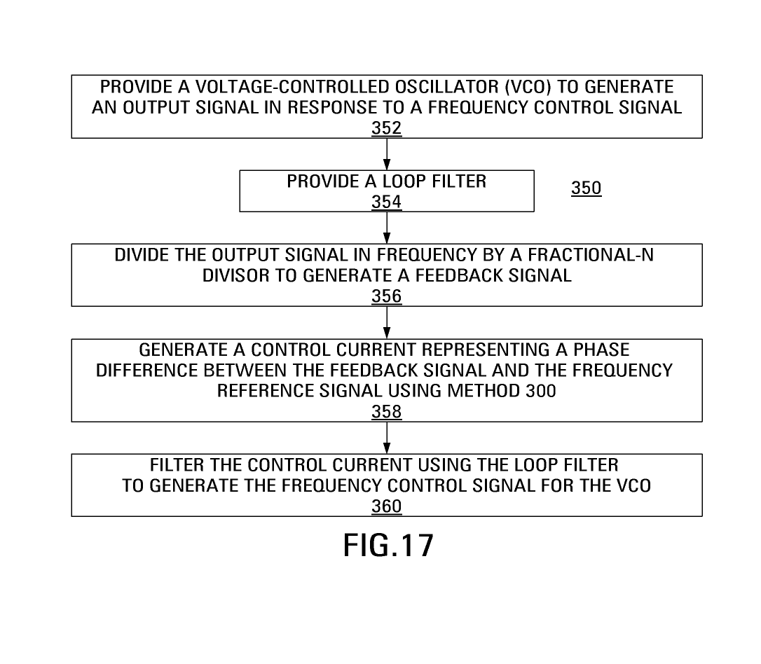

FIG. 17 is a flowchart showing an example 350 of a method of generating an output signal having a frequency defined by a frequency reference signal based on phase-frequency detection method 300.

In block 352, a voltage-controlled oscillator (VCO) is provided to generate the output signal in response to a frequency control signal.

In block 354, a loop filter is provided.

In block 356, the output signal is divided in frequency by a fractional-N divisor to generate a feedback signal.

In block 358, an output current representing a phase difference between the feedback signal and the frequency reference signal is generated using method 300 described above with reference to FIG. 16.

In block 360, the output current is filtered using the loop filter to generate the frequency control signal for the VCO.

In an example, an embodiment of PLL circuit 10 described above with reference to FIG. 1 that includes an embodiment of charge pump phase-frequency detector 150 described above with reference to FIG. 8 performs an embodiment of method 350. In another example, an embodiment of PLL circuit 10 described above with reference to FIG. 1 that includes an embodiment of charge pump phase-frequency detector 170 described above with reference to FIG. 14 performs an embodiment of method 350.

This disclosure describes the invention in detail using illustrative embodiments. However, the invention defined by the appended claims is not limited to the precise embodiments described.

I claim:

1. A charge-pump phase-frequency detector (CPPFD), comprising:
a first flip-flop, comprising a data input connected to a fixed logic level, a reset input, a data output, and a clock input connected to receive a frequency reference signal;
a second flip-flop, comprising a data input connected to fixed logic level, a reset input, a data output, and a clock input connected to receive a feedback signal;
a first delay circuit and a second delay circuit;
a reset gate, comprising a first input connected to the data output of the first flip-flop, a second input connected to the data output of the second flip-flop, and an output connected to the reset inputs of the flip-flops via the first delay circuit; and
a charge pump circuit, comprising an up input connected to the data output of the first flip-flop via the second delay circuit, a down input connected to the data output of the second flip-flop, and a control current output.

2. The CPPFD of claim 1, in which the current pump comprises a current source to output to the control current output a source current in response to one of (a) a delayed up control signal received from the data output of the first flip-flop via the second delay circuit, and (b) a down control signal received from the data output of the second flip-flop, and a current sink to receive from the control current output a sink current in response to the other of (a) the delayed up control signal, and (b) the down control signal, a difference between the source current and the sink current constituting a control current.

3. The CPPFD of claim 2, in which the second delay circuit imposes a delay time sufficient to ensure that the current controlled by the down control signal always leads the current controlled by the up control signal, and to prevent the rising edges of the currents from overlapping, where the currents increase in magnitude at their rising edges.

4. The CPPFD of claim 2, in which the second delay circuit imposes a delay time greater than a sum of a largest time delay between the feedback signal and the frequency reference signal when the feedback signal lags frequency reference signal, and the greater of the rise time of the source current and the rise time of the sink current,
i.e., DT_{UP}≧TD_{G}+max(TR_{SC},TR_{SK})
where:
DT_{UP} is the delay time imposed by the second delay circuit;
TD_{G} is the largest time delay between the feedback signal and the frequency reference signal when the feedback signal lags frequency reference signal;
TR_{SC} is the rise time of the source current; and
TR_{SK} is the rise time of the sink current.

5. The CPPFD of claim 2, in which the first delay circuit imposes a delay time greater than the greater of:
a product of:
a quotient of:
a difference between the voltage at the data outputs of the flip-flops corresponding a high logic state and the reset input voltage of the reset gate; and
a difference between the voltage at the data outputs of the flip-flops corresponding to the high logic state, and the voltage at the data outputs of the flip-flops corresponding to the low logic state, and
the rise time of the data outputs of the flip-flops from the low logic state to the high logic state; and
a sum of:
the largest time delay between the feedback signal and frequency reference signal when the feedback signal lags frequency reference signal, and
the greater of the rise time of the sink current and the rise time of the source current, i.e.,
$${DT}_{FB} \geq max \{ \frac{{V}_{OH} - {V}_{RI}}{{V}_{OH} - {V}_{OL}} \cdot {TR}_{LH} , {TD}_{G} + max ( {TR}_{SC} , {TR}_{SK} ) \} ,$$
where:
DT_{FB} is the delay time imposed by the first delay circuit;
V_{OH} is the voltage at the data outputs of the flip-flops corresponding to the high logic state;
V_{OL} is the voltage at the outputs of the flip-flops corresponding to the low logic state;
TR_{LH} is the rise time of the data outputs of the flip-flops from the low logic state to the high logic state;
V_{RI} is reset input voltage of the reset gate;
TD_{G} is the largest time delay between the feedback signal and the frequency reference signal when the feedback signal lags the frequency reference signal;
TR_{SC} is the rise time of the source current; and
TR_{SK} is the rise time of the source current.

6. The CPPFD of claim 2, in which:
a one of the delayed up control signal and the down control signal that lags the other of the control signals is a lagging control signal, the one of the current source and the current sink controlled by the lagging control signal is a lagging current generator, the current output by the lagging current generator is a lagging control current, and the lagging current generator has a control threshold;
an elapsed time between the rising and falling edges of the one of the delayed up control signal crossing the control threshold of the lagging current generator is less than the rise time of the lagging control current; and
the first delay circuit imposes a delay time DT′_{FB} greater than the greater of:
$$\{ \frac{{V}_{OH} - {V}_{RI}}{{V}_{OH} - {V}_{OL}} \cdot {TR}_{LH} \} + max ( 0 , \{ max ( {TR}_{SC} , {TR}_{SK} ) - [ \{ \frac{{V}_{OH} - {V}_{TC}}{{V}_{OH} - {V}_{OL}} \cdot {TR}_{LH} \} - \{ \frac{{V}_{OH} - {V}_{TC}}{{V}_{OH} - {V}_{OL}} \cdot {TF}_{HL} \} ] \} ) , \\ and$$
$${TD}_{G} + max ( {TR}_{SC} , {TR}_{SK} ) ,$$
where:
V_{OH} is the voltage at the data outputs of the flip-flops corresponding to the high logic state;
V_{RI} is reset input voltage of the reset gate;
V_{OL} is the voltage at the outputs of the flip-flops corresponding to the low logic state;
TR_{LH} is the rise time of the data outputs of the flip-flops from the low logic state to the high logic state;
TR_{SC} is the rise time of the source current;
TR_{SK} is the rise time of the source current;
V_{TC} is the control threshold of the lagging current generator;
TR_{LH} is the rise time of the lagging control signal from the low logic state to the high logic state;
TF_{HL} is the fall time of the lagging control signal from the high logic state to the low logic state;
TD_{G} is the largest time delay between the feedback signal and the frequency reference signal when the feedback signal lags the frequency reference signal.

7. A phase-lock loop circuit, comprising:
a voltage-controlled oscillator (VCO) to generate an output signal, the VCO comprising a control input;
a charge-pump phase-frequency detector (CPPFD) in accordance with claim 1 in which the control current output of the charge pump circuit is coupled to the control input of the VCO; and
a frequency divider circuit to divide the frequency of the output signal by a fractional-N divisor to provide the feedback signal received by the second flip-flop of the CPPFD, the frequency divider circuit comprising a sigma-delta modulator.

8. The phase-lock loop circuit of claim 7, in which:
the phase-lock loop circuit additionally comprises a loop filter; and
the control current output of the charge pump circuit is coupled to the control input of the VCO via the loop filter.

9. A charge-pump phase-frequency detector (CPPFD), comprising:
a first flip-flop, comprising a data input connected to a fixed logic level, a reset input, a data output, and a clock input connected to receive a frequency reference signal;
a second flip-flop, comprising a data input connected to fixed logic level, a reset input, a data output, and a clock input connected to receive a feedback signal;
a first delay circuit and a second delay circuit;
a reset gate, comprising a first input connected to the data output of the first flip-flop, a second input connected to the data output of the second flip-flop, and an output connected to the reset inputs of the flip-flops via the first delay circuit; and
a charge pump circuit, comprising an up input connected via the second delay circuit to receive an up control signal from the data output of the first flip-flop, a down input connected via the second delay circuit to receive a down control signal from the data output of the second flip-flop, and a control current output, in which:
the second delay circuit is to delay one of the up control signal and the down control signal relative to the other of the up control signal and the down control signal.

10. The CPPFD of claim 9, in which the current pump comprises a current source to output to the control current output a source current in response to one of (a) the up control signal, and (b) the down control signal; and a current sink to receive from the control current output a sink current in response to the other of (a) the up control signal, and (b) the down control signal, a difference between the source current and the sink current constituting a control current.

11. The CPPFD of claim 10, in which the second delay circuit delays the one of control signals relative to the other of the control signals by a delay time sufficient to ensure that the current controlled by the other of the control signals always leads the current controlled by one of the control signals, and to prevent the rising edges of the currents from overlapping, where the currents increase in magnitude at their rising edges.

12. The CPPFD of claim 11, in which:
when the second delay circuit is to delay the up control signal relative to the down control signal, the second delay circuit is to delay the up control signal relative to the down control signal by a delay time greater than a sum of the largest time delay between the feedback signal and the frequency reference signal when the feedback signal lags the frequency reference signal, and the greater of the rise time of the source current and the rise time of the sink current;
i.e., DT_{UP}≧TD_{G}+max(TR_{SC},TR_{SK}); and
when the second delay circuit is to delay the down control signal relative to the up control signal, the second delay circuit is to delay the down control signal relative to the up control signal by a delay time greater than a sum of the largest time delay between the feedback signal and the frequency reference signal when the feedback signal leads the frequency reference signal, and the greater of the rise time of the source current and the rise time of the sink current;
i.e., DT_{DN}≧TD_{D}+max(TR_{SC},TR_{SK});
where:
DT_{UP} is the delay time imposed by the second delay circuit on the up control signal relative to the down control signal;
DT_{DN} is the delay time imposed by the second delay circuit on the down control signal relative to the up control signal;
TD_{G} is the largest time delay between the feedback signal and the frequency reference signal when the feedback signal lags the frequency reference signal;
TD_{D} is the largest time delay between the feedback signal and the frequency reference signal RS when the feedback signal leads the frequency reference signal;
TR_{SC} is the rise time of the source current; and
TR_{SK} is the rise time of the sink current.

13. The CPPFD of claim 11, in which the first delay circuit imposes a delay time greater than the greater of:
a product of:
a quotient of:
a difference between the voltage at the data outputs of the flip-flops corresponding a high logic state and the reset input voltage of the reset gate; and
a difference between the voltage at the data outputs of the flip-flops corresponding to the high logic state, and the voltage at the data outputs of the flip-flops corresponding to the low logic state, and
the rise time of the data outputs of the flip-flops from the low logic state to the high logic state; and
a sum of:
when the second delay circuit is to delay the up control signal relative to the down control signal, the largest time delay between the feedback signal and frequency reference signal when the feedback signal lags the frequency reference signal; and
when the second delay circuit is to delay the down control signal relative to the up control signal, the largest time delay between the feedback signal and frequency reference signal when the feedback signal leads the frequency reference signal, and
the greater of the rise time of the source current and the rise time of the sink current, i.e.,
$${DT}_{FB} \geq max \{ \frac{{V}_{OH} - {V}_{RI}}{{V}_{OH} - {V}_{OL}} \cdot {TR}_{LH} , {TD}_{L} + max ( {TR}_{SC} , {TR}_{SK} ) \} ,$$
where:
DT_{FB} is the delay time imposed by the first delay circuit;
V_{OH} is the voltage at the data outputs of the flip-flops corresponding to the high logic state;
V_{OL} is the voltage at the outputs of the flip-flops corresponding to the low logic state;
TR_{LH} is the rise time of the data outputs of the flip-flops from the low logic state to the high logic state;
V_{RI} is the reset input voltage of the reset gate;
when the second delay circuit is to delay the up control signal relative to the down control signal, TD_{L} is the largest time delay between the feedback signal and the frequency reference signal when the feedback signal lags the frequency reference signal;
when the second delay circuit is to delay the down control signal relative to the up control signal, TD_{L} is the largest time delay between the feedback signal and the frequency reference signal when the feedback signal leads the frequency reference signal;
TR_{SC} is the rise time of the source current; and
TR_{SK} is the rise time of the sink current.

14. The CPPFD of claim 11, in which:
the one of the up control signal and the down control signal delayed relative to the other of the up control signal and the down control signal is a lagging control signal, the one of the current source and the current sink controlled by the lagging control signal is a lagging current generator, the current output by the lagging current generator is a lagging control current, and the lagging current generator has a control threshold;
an elapsed time between the rising and falling edges of the one of the delayed up control signal crossing the control threshold of the lagging current generator is less than the rise time of the lagging control current; and
the first delay circuit imposes a delay time DT′_{FB} greater than the greater of:
$$\{ \frac{{V}_{OH} - {V}_{RI}}{{V}_{OH} - {V}_{OL}} \cdot {TR}_{LH} \} + max ( 0 , \{ max ( {TR}_{SC} , {TR}_{SK} ) - [ \{ \frac{{V}_{OH} - {V}_{TC}}{{V}_{OH} - {V}_{OL}} \cdot {TR}_{LH} \} - \{ \frac{{V}_{OH} - {V}_{TC}}{{V}_{OH} - {V}_{OL}} \cdot {TF}_{HL} \} ] \} ) , \\ and$$
$${TD}_{L .} + max ( {TR}_{SC} , {TR}_{SK} ) ,$$
where:
V_{OH} is the voltage at the data outputs of the flip-flops corresponding to the high logic state;
V_{RI} is reset input voltage of the reset gate;
V_{OL} is the voltage at the outputs of the flip-flops corresponding to the low logic state;
TR_{LH} is the rise time of the data outputs of the flip-flops from the low logic state to the high logic state;
TR_{SC} is the rise time of the source current;
TR_{SK} is the rise time of the source current;
V_{TC} is the control threshold of the lagging current generator,
TR_{LH} is the rise time of the lagging control signal from the low logic state to the high logic state;
TF_{HL} is the fall time of the lagging control signal from the high logic state to the low logic state;
when the second delay circuit is to delay the up control signal relative to the down control signal, TD_{L} is the largest time delay between the feedback signal and the frequency reference signal when the feedback signal lags frequency reference signal; and
when the second delay circuit is to delay the down control signal relative to the up control signal, TD_{L} is the largest time delay between the feedback signal and the frequency reference signal when the feedback signal leads the frequency reference signal.

15. A phase detection method, comprising:
receiving a frequency reference signal and a feedback signal;
providing a current source to output a source current, and a current sink to sink a sink current;
differencing the source current and the sink current to generate an output current representing a phase difference between the feedback signal and the frequency reference signal;
setting an up control signal in response to an edge of the frequency reference signal;
setting a down control signal in response to an edge of the feedback signal;
resetting the up control signal and the down control signal a defined first delay time after a lagging one of the up control signal and the down control signal has been set;
turning one of the source current and the sink current on and off in response to the setting and the resetting, respectively, of the up control signal;
turning the other of the source current and the sink current on and off in response to the setting and the resetting, respectively, of the down control signal; and
delaying one of the up control signal and the down control signal relative to the other of the up control signal and the down control signal by a second time delay.

16. The phase detection method of claim 15, in which the second delay time sufficient to ensure that the current controlled by the other of the control signals always leads the current controlled by the one of the control signals, and to prevent the rising edges of the currents from overlapping, where the currents increase in magnitude at their rising edges.

17. The phase detection method of claim 16, in which:
when the delaying delays the up control signal relative to the down control signal, the second delay time is greater than a sum of:
the largest time delay between the feedback signal and the frequency reference signal when the feedback signal lags frequency reference signal; and
the greater of the rise time of the source current, and the rise time of the sink current,
i.e., DT_{UP}≧TD_{G}+max(TR_{SC},TR_{SK}); and
when the delaying delays the down control signal relative to the up control signal, the second delay time is greater than a sum of:
the largest time delay between the feedback signal and the frequency reference signal when the feedback signal leads the frequency reference signal; and
the greater of the rise time of the source current, and the rise time of the sink current,
i.e., DT_{DN}≧TD_{D}+max(TR_{SC},TR_{SK});
where:
DT_{UP} is the second delay time when the delaying delays the up control signal relative to the down control signal;
DT_{DN} is the second delay time when the delaying delays the down control signal relative to the up control signal;
TD_{G} is the largest time delay between the feedback signal and the frequency reference signal when the feedback signal lags frequency reference signal;
TD_{D} is the largest time delay between the feedback signal and the frequency reference signal when the feedback signal leads the frequency reference signal;
TR_{SC} is the rise time of the source current; and
TR_{SK} is the rise time of the sink current.

18. The phase detection method of claim 16, in which the first delay time is greater than the greater of:
a product of:
a quotient of:
a difference between the voltage of the control signals corresponding the set state and the maximum voltage attained by the lagging one of the control signals when the control signals are reset; and
a difference between the voltage of the control signals corresponding to the set state, and the voltage of the control signals corresponding to the reset state, and
the rise time of the control signals from the reset state to the set state; and
a sum of:
when the delaying delays the up control signal relative to the down control signal, the largest time delay between the feedback signal and frequency reference signal when the feedback signal lags frequency reference signal; and
when the delaying delays the down control signal relative to the up control signal, the largest time delay between the feedback signal and frequency reference signal when the feedback signal leads frequency reference signal, and
the greater of the rise time of the source current and the rise time of the sink current, i.e.,
$${DT}_{FB} \geq max \{ \frac{{V}_{OH} - {V}_{RI}}{{V}_{OH} - {V}_{OL}} \cdot {TR}_{LH} , {TD}_{L} + max ( {TR}_{SC} , {TR}_{SK} ) \} ,$$
where:
DT_{FB} is the first delay time;
V_{OH} is a voltage of the control signals corresponding to the set state;
V_{OL} is the voltage of the control signals corresponding to the reset state;
TR_{LH} is a rise time of the control signals from the reset state to the set state;
V_{RI} is a maximum voltage attained by the lagging one of the control signals when the control signals are reset;
when the delaying delays the up control signal relative to the down control signal, TD_{L} is the largest time delay between the feedback signal and the frequency reference signal when the feedback signal lags the frequency reference signal;
when the delaying delays the down control signal relative to the up control signal, TD_{L} is the largest time delay between the feedback signal and the frequency reference signal when the feedback signal leads the frequency reference signal;
TR_{SC} is the rise time of the source current, and
TR_{SK} is the rise time of the sink current.

19. The phase detection method of claim 16, in which:
the one of the up control signal and the down control signal delayed relative to the other of the up control signal and the down control signal is a lagging control signal, the one of the source current and the sink current controlled by the lagging control signal is a lagging control current, and control of the lagging control current by the lagging control signal is subject to a control threshold;
an elapsed time between the rising and falling edges of the one of the up control signal crossing the control threshold of the lagging current generator is less than the rise time of the lagging control current;
the resetting is subject to a reset threshold; and
the first delay DT′_{F} greater than the greater of:
$$\{ \frac{{V}_{OH} - {V}_{RI}}{{V}_{OH} - {V}_{OL}} \cdot {TR}_{LH} \} + max ( 0 , \{ max ( {TR}_{SC} , {TR}_{SK} ) - [ \{ \frac{{V}_{OH} - {V}_{TC}}{{V}_{OH} - {V}_{OL}} \cdot {TR}_{LH} \} - \{ \frac{{V}_{OH} - {V}_{TC}}{{V}_{OH} - {V}_{OL}} \cdot {TF}_{HL} \} ] \} ) , \\ and$$
$${TD}_{L} + max ( {TR}_{SC} , {TR}_{SK} ) ,$$
where:
V_{OH} is the voltage at the control signals corresponding to the set state;
V_{RI} is reset threshold;
V_{OL} is the voltage of the control signals corresponding to the low logic state;
TR_{LH} is the rise time of the control signals from the low logic state to the high logic state;
TR_{SC} is the rise time of the source current;
TR_{SK} is the rise time of the sink current;
V_{TC} is the control threshold of the lagging control current;
TR_{LH} is the rise time of the lagging control signal from the low logic state to the high logic state;
TF_{HL} is the fall time of the lagging control signal from the high logic state to the low logic state;
when the delaying delays the up control signal relative to the down control signal, TD_{L} is the largest time delay between the feedback signal and the frequency reference signal when the feedback signal lags the frequency reference signal; and
when the delaying delays the down control signal relative to the up control signal, TD_{L} is the largest time delay between the feedback signal and the frequency reference signal when the feedback signal leads the frequency reference signal.

20. A method of generating an output signal having a frequency defined by a frequency reference signal, the method comprising:
providing a voltage-controlled oscillator (VCO) to generate the output signal in response to a frequency control signal;
providing a loop filter;
dividing the output signal in frequency by a fractional-N divisor to generate a feedback signal;
generating an output current representing a phase difference between the feedback signal and the frequency reference signal using the method of claim 15; and
filtering the output current using the loop filter to generate the frequency control signal for the VCO.
